(19) United States
(12) Patent Application Publication
(10) Pub. No.: US 2025/0234664 A1
(43) Pub. Date: Jul. 17, 2025

(54) PHOTOELECTRIC CONVERSION APPARATUS, PHOTOELECTRIC CONVERSION SYSTEM, MOVING BODY, AND EQUIPMENT

(71) Applicant: CANON KABUSHIKI KAISHA, Tokyo (JP)

(72) Inventors: ALICE MORIMOTO, Kanagawa (JP); KAZUHIRO MORIMOTO, Kanagawa (JP)

(21) Appl. No.: 18/989,568

(22) Filed: Dec. 20, 2024

(30) Foreign Application Priority Data
Jan. 17, 2024 (JP) 2024-005561

(51) Int. Cl. H10F 39/00

(52) U.S. Cl. CPC H10F 39/807; H10F 39/805

(57) ABSTRACT

A photoelectric conversion apparatus is provided. The apparatus includes: a semiconductor layer having a first main surface and a second main surface and including a first avalanche photodiode and a second avalanche photodiode adjacent to each other; and a trench extending from the first main surface toward the second main surface. At least a part of the trench is arranged between the first avalanche photodiode and the second avalanche photodiode, a first conductive portion and a second conductive portion are arranged in the trench, and in an orthogonal projection to the first main surface, the first conductive portion and the second conductive portion are arranged apart from each other in the trench.

### BACKGROUND OF THE INVENTION

### Field of the Invention

The present disclosure relates to a photoelectric conversion apparatus, a photoelectric conversion system, a moving body, and equipment.

### Description of the Related Art

An avalanche photodiode (APD) capable of detecting light at the level of a single photon is known. Japanese Patent Laid-Open No. 2015-041746 describes a single photon avalanche photodiode (SPAD) that can be used to detect one photon by applying a high reverse bias to a p-n junction to form a high electric field region (avalanche breakdown region).

During carrier multiplication, if avalanche light emission occurs in which carriers excited in the high electric field region emit photons, a crosstalk may occur in which light is detected by a pixel adjacent to the pixel where light emission occurs.

### SUMMARY OF THE INVENTION

According to some embodiments, a photoelectric conversion apparatus comprising: a semiconductor layer having a first main surface and a second main surface and including a first avalanche photodiode and a second avalanche photodiode adjacent to each other; and a trench extending from the first main surface toward the second main surface, wherein at least a part of the trench is arranged between the first avalanche photodiode and the second avalanche photodiode, a first conductive portion and a second conductive portion are arranged in the trench, and in an orthogonal projection to the first main surface, the first conductive portion and the second conductive portion are arranged apart from each other in the trench, is provided.

According to some embodiments of the present disclosure, a technique advantageous in suppressing a crosstalk can be provided.

Further features of the present invention will become apparent from the following description of exemplary embodiments (with reference to the attached drawings).

### BRIEF DESCRIPTION OF THE DRAWINGS

FIG. 1 is a view showing an arrangement example of a photoelectric conversion apparatus according to an embodiment;

FIG. 2 is a view showing an arrangement example of the pixel array of the photoelectric conversion apparatus shown in FIG. 1;

FIG. 3 is a block diagram showing an arrangement example of the photoelectric conversion apparatus shown in FIG. 1;

FIG. 4 is a circuit diagram showing an arrangement example of the pixel of the photoelectric conversion apparatus shown in FIG. 1;

FIGS. 5A and 5B are views for explaining an operation example of the pixel of the photoelectric conversion apparatus shown in FIG. 1;

FIGS. 6A and 6B are plan views showing an arrangement example of the pixels of the photoelectric conversion apparatus shown in FIG. 1;

FIGS. 7A and 7B are sectional views showing the arrangement example of the pixels shown in FIGS. 6A and 6B;

FIGS. 8A and 8B are sectional views showing an example of a manufacturing step of the pixels shown in FIGS. 6A and 6B;

FIGS. 9A and 9B are sectional views showing the example of the manufacturing step of the pixels shown in FIGS. 6A and 6B;

FIGS. 10A and 10B are sectional views showing the example of the manufacturing step of the pixels shown in FIGS. 6A and 6B;

FIGS. 11A and 11B are sectional views showing the example of the manufacturing step of the pixels shown in FIGS. 6A and 6B;

FIGS. 12A to 12C are plan views showing an arrangement example of the pixels of the photoelectric conversion apparatus shown in FIG. 1;

FIGS. 13A and 13B are sectional views showing the arrangement example of the pixels shown in FIGS. 12A to 12C;

FIGS. 14A and 14B are sectional views showing an example of a manufacturing step of the pixels shown in FIGS. 12A to 12C;

FIGS. 15A and 15B are sectional views showing the example of the manufacturing step of the pixels shown in FIGS. 12A to 12C;

FIGS. 16A and 16B are sectional views showing the example of the manufacturing step of the pixels shown in FIGS. 12A to 12C;

FIGS. 17A and 17B are sectional views showing the example of the manufacturing step of the pixels shown in FIGS. 12A to 12C;

FIGS. 18A and 18B are sectional views showing the example of the manufacturing step of the pixels shown in FIGS. 12A to 12C;

FIGS. 19A and 19B are sectional views showing the example of the manufacturing step of the pixels shown in FIGS. 12A to 12C;

FIGS. 20A and 20B are sectional views showing the example of the manufacturing step of the pixels shown in FIGS. 12A to 12C;

FIGS. 21A and 21B are sectional views showing the example of the manufacturing step of the pixels shown in FIGS. 12A to 12C;

FIGS. 22A and 22B are plan views showing an arrangement example of the pixels of the photoelectric conversion apparatus shown in FIG. 1;

FIGS. 23A and 23B are sectional views showing the arrangement example of the pixels shown in FIGS. 22A and 22B;

FIGS. 24A and 24B are plan views showing an arrangement example of the pixels of the photoelectric conversion apparatus shown in FIG. 1;

FIGS. 25A and 25B are sectional views showing the arrangement example of the pixels shown in FIGS. 24A and 24B;

FIGS. 26A and 26B are plan views showing a modification of the pixels shown in FIGS. 24A and 24B;

FIGS. 27A and 27B are plan views showing a modification of the pixels shown in FIGS. 24A and 24B;

FIGS. 28A and 28B are sectional views showing the arrangement example of the pixels shown in FIGS. 27A and 27B;

FIG. 29 is a functional block diagram of a photoelectric conversion system using the photoelectric conversion apparatus according to the embodiment;

FIG. 30A is a functional block diagram of a photoelectric conversion system using the photoelectric conversion apparatus according to the embodiment;

FIG. 30B is a functional block diagram of a moving body using the photoelectric conversion apparatus according to the embodiment;

FIG. 31 is a functional block diagram of a photoelectric conversion system using the photoelectric conversion apparatus according to the embodiment;

FIG. 32 is a functional block diagram of a photoelectric conversion system using the photoelectric conversion apparatus according to the embodiment;

FIG. 33A is a view showing a photoelectric conversion system using the photoelectric conversion apparatus according to the embodiment; and

FIG. 33B is a view showing a photoelectric conversion system using the photoelectric conversion apparatus according to the embodiment;

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

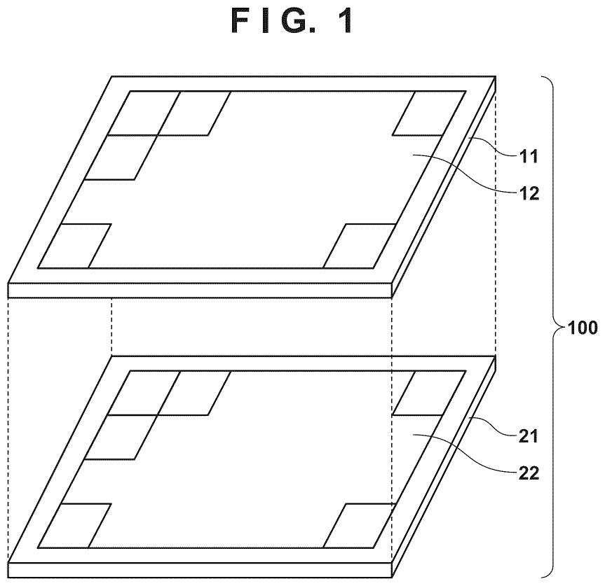

First, with reference to FIGS. 1 to 5, an avalanche photodiode (to be sometimes referred to as an APD hereinafter) that can be used in a photoelectric conversion apparatus 100 to be described below will be described. FIG. 1 is a view showing an arrangement example of the photoelectric conversion apparatus 100. The photoelectric conversion apparatus 100 can be constituted by stacking two boards, that is, a sensor board 11 (to be sometimes simply referred to as a board 11) and a circuit board 21 and electrically connecting them. That is, the photoelectric conversion apparatus 100 may be a stacked device. In the board 11, a semiconductor layer 301 in which a plurality of pixels 101 are arranged, and the like are arranged, which will be described later. A pixel region 12 including the plurality of pixels 101 is arranged in the board 11. A circuit region 22 where a signal detected in the pixel region 12 is processed is arranged in the circuit board 21.

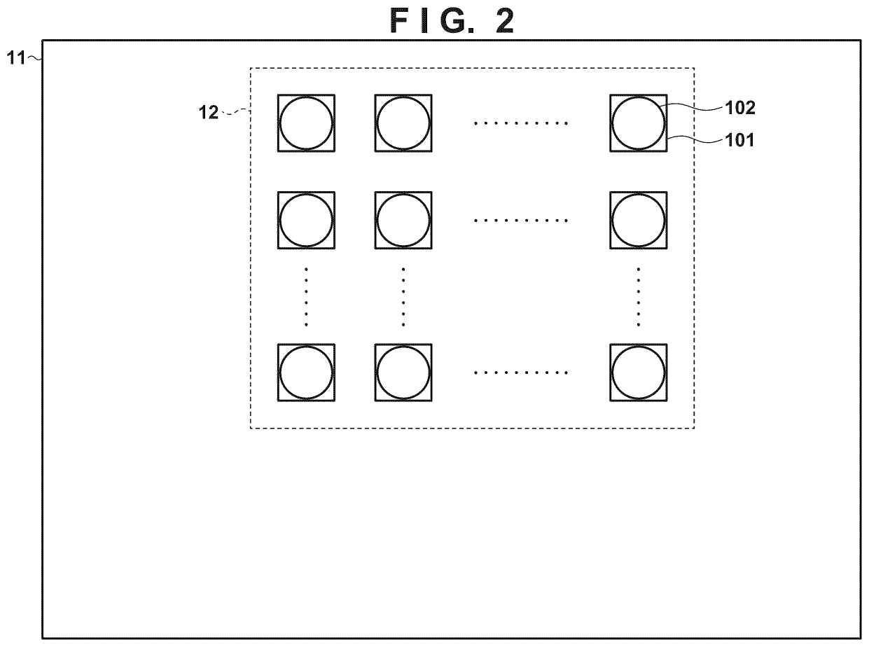

FIG. 2 is a view showing an arrangement example of the board 11. The pixels 101 each having a photoelectric conversion element 102 including an APD are arranged in a two dimensional array in an orthogonal projection to a main surface 391 of the board 11, forming the pixel region 12. The pixel 101 is typically a pixel for generating an image, but when it is used in a Time of Flight (ToF) distance measurement device, may not always generate an image. That is, the pixel 101 may be configured to measure the time when light arrives and the quantity of light.

FIG. 3 is a block diagram showing an arrangement example of the circuit board 21. The circuit board 21 includes signal processing circuits 103 that process charges photoelectrically converted by the photoelectric conversion elements 102 shown in FIG. 2, a readout circuit 112, a control pulse generation circuit 115, a horizontal scanning circuit 111, signal lines 113, a vertical scanning circuit 110, and the like. The signal processing circuits 103 shown in FIG. 3 may be arranged so as to correspond to each pixel 101 shown in FIG. 2. In this case, the pixel 101 (photoelectric conversion elements 102) and the signal processing circuit 103 may be electrically connected via a connection wiring provided for each pixel 101.

The vertical scanning circuit 110 receives a control pulse supplied from the control pulse generation circuit 115, and supplies a control pulse to the respective pixels 101 via driving lines 116. A logic circuit such as a shift register or an address decoder can be used for the vertical scanning circuit 110.

A signal output from the pixel 101 is processed by the signal processing circuit 103. A counter, a memory, and the like can be provided in the signal processing circuit 103. The memory can hold, as a digital value, a count value obtained by counting by the counter.

The horizontal scanning circuit 111 inputs, to the signal processing circuits 103, a control pulse for sequentially selecting respective columns in order to read out signals from the memories of the signal processing circuits 103 corresponding to the respective pixels 101 in which digital signals are held. As for a selected column, a signal is output to the signal line 113 from the signal processing circuit 103 corresponding to the pixel 101 selected by the vertical scanning circuit 110. The signal output to the signal line 113 is output via an output circuit 114 to a recording unit or a signal processing unit outside the photoelectric conversion apparatus 100.

The array of the pixels 101 in the pixel region 12 shown in FIG. 2 is not limited to a two-dimensional array. The pixels 101 may be arranged one-dimensionally. The function of the signal processing circuit 103 need not always be provided one by one in all the pixels 101 (photoelectric conversion elements 102). For example, one signal processing circuit 103 may be shared between the plurality of pixels 101 (photoelectric conversion elements 102) to sequentially perform signal processing.

As shown in FIGS. 2 and 3, the signal processing circuits 103 can be arranged in a region overlapping the pixel region 12 in an orthogonal projection to the pixel region 12. The vertical scanning circuit 110, the horizontal scanning circuit 111, the readout circuit 112, the output circuit 114, the control pulse generation circuit 115, and the like can be so arranged as to overlap a gap between the end of the board 11 and that of the pixel region 12. In other words, the board 11 has the pixel region 12 and a non-pixel region arranged around the pixel region 12. In this case, the vertical scanning circuit 110, the horizontal scanning circuit 111, the readout circuit 112, the output circuit 114, and the control pulse generation circuit 115 can be arranged in a region overlapping the non-pixel region.

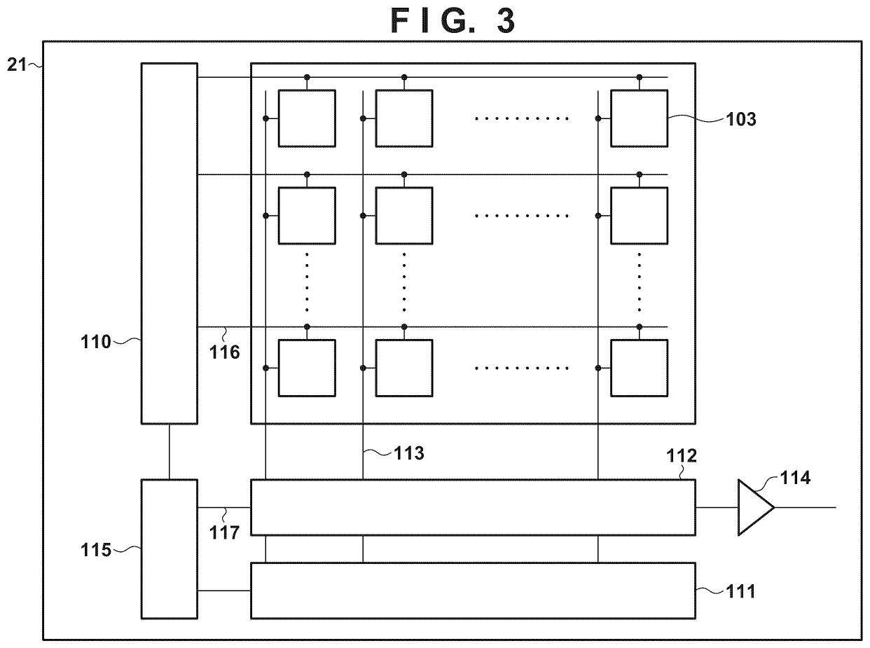

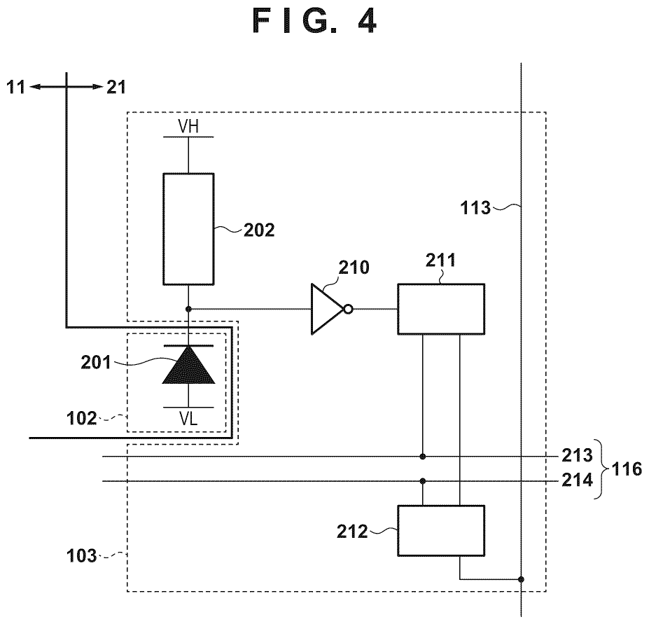

FIG. 4 shows an example of a block diagram including an equivalent circuit focusing on one pixel 101 (photoelectric conversion element 102). In FIG. 4, the photoelectric conversion element 102 including an APD 201 is provided in the board 11, and the remaining components are provided in the circuit board 21.

The APD 201 generates a charge pair corresponding to incident light by photoelectric conversion. A potential VL is supplied to the anode of the APD 201. A potential VH higher than the potential VL supplied to the anode is supplied to the cathode of the APD 201. A reverse bias voltage is supplied to the anode and the cathode so that the APD 201 performs an avalanche breakdown operation. In a state in which such a reverse bias voltage is supplied, charges generated by incident light cause avalanche breakdown, generating an avalanche current.

In a case where the reverse bias voltage is supplied to the APD 201, there are a Geiger mode in which the APD 201 is operated by a potential difference (voltage) between the anode and the cathode larger than a breakdown voltage, and a linear mode in which the APD 201 is operated by a potential difference between the anode and the cathode around the breakdown voltage or equal to or lower than the breakdown voltage. An APD operated in the Geiger mode is called a Single Photon Avalanche Diode (SPAD). For example, the potential VL is −30 V, and the potential VH is 1 V. The APD 201 may be operated in the linear mode or the Geiger mode.

A quench element 202 is connected between a power supply that supplies the potential VH, and the APD 201. The quench element 202 functions as a load circuit (quench circuit) at the time of signal multiplication by avalanche breakdown, and operates to suppress a voltage supplied to the APD 201 and suppress avalanche breakdown (quench operation). The quench element 202 also operates to return the voltage supplied to the APD 201 to a voltage (VH-VL) by supplying a current by an amount corresponding to a voltage drop caused by the quench operation (recharge operation).

The signal processing circuit 103 can include a waveform shaping circuit 210, a counter circuit 211, and a selection circuit 212. In this specification, the signal processing circuit 103 suffices to include any of the waveform shaping circuit 210, the counter circuit 211, and the selection circuit 212.

The waveform shaping circuit 210 shapes a potential change of the cathode of the APD 201 that is obtained at the time of photon detection, and outputs a pulse signal. As the waveform shaping circuit 210, for example, an inverter circuit is used. In the arrangement shown in FIG. 4, the use of one inverter as the waveform shaping circuit 210 is exemplified. However, the present invention is not limited to this, and a circuit constituted by series-connecting a plurality of inverters may be used as the waveform shaping circuit 210 or another circuit having the waveform shaping effect may be used.

The counter circuit 211 counts pulse signals output from the waveform shaping circuit 210 and holds the count value. When a control pulse pRES is supplied from the vertical scanning circuit 110 shown in FIG. 3 via a driving line 213 corresponding to a part of the driving line 116 shown in FIG. 3, the signal held by the counter circuit 211 is reset.

The selection circuit 212 receives a control pulse pSEL from the vertical scanning circuit 110 via a driving line 214 corresponding to a part of the driving line 116 shown in FIG. 3, and switches electrical connection/disconnection between the counter circuit 211 and the signal line 113. The selection circuit 212 includes, for example, a buffer circuit for outputting a signal.

A switching element such as a transistor may be interposed between the quench element 202 and the APD 201 or between the photoelectric conversion element 102 and the signal processing circuit 103 so that electrical connection can be switched. Similarly, supply of the potential VH or potential VL to the photoelectric conversion element 102 may be electrically switchable using a switching element such as a transistor.

In this embodiment, the counter circuit 211 is arranged in the signal processing circuit 103. However, the present invention is not limited to this, and a Time-to-Digital Converter (TDC) and a memory may be used instead of the counter circuit 211 so that the photoelectric conversion apparatus 100 obtains a pulse detection timing. In this case, the generation timing of a pulse signal output from the waveform shaping circuit 210 is converted into a digital signal by the TDC. The TDC receives a control pulse pREF (reference signal) from the vertical scanning circuit 110 via the driving line 116 for measurement of the timing of the pulse signal. By using the control pulse pREF as a reference, the TDC obtains, as a digital signal, a signal when the input timing of a signal output from each pixel 101 via the waveform shaping circuit 210 is regarded as a relative time.

In the arrangement shown in FIG. 4, the quench element 202, the waveform shaping circuit 210, the counter circuit 211, and the selection circuit 212 are arranged in one circuit board 21. However, the present invention is not limited to this. For example, the quench element 202 and the waveform shaping circuit 210 may be arranged in one substrate, the counter circuit 211 and the selection circuit 212 may be arranged in another substrate, and these substrates may be stacked.

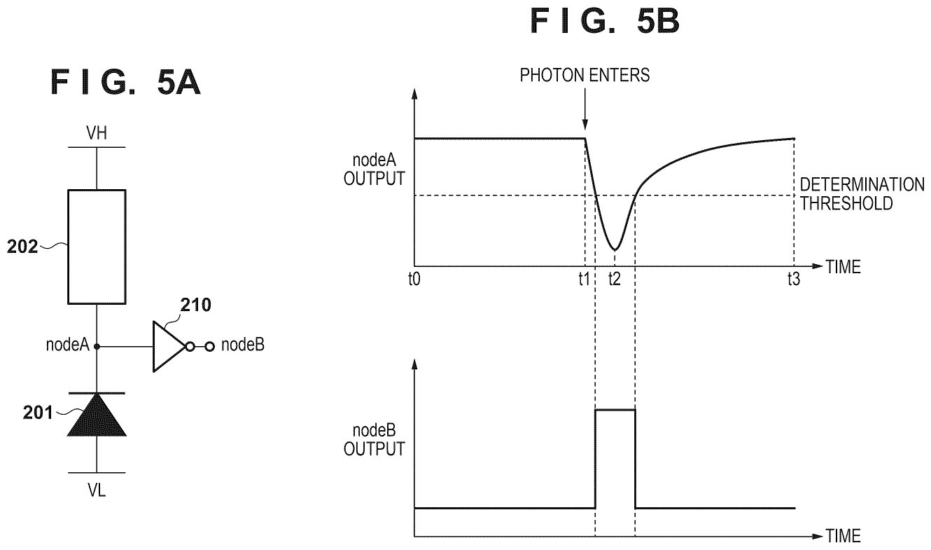

FIGS. 5A and 5B are views schematically showing the relationship between the operation of the APD 201 and an output signal. FIG. 5A is a view showing an excerpt of the APD 201, quench element 202, and waveform shaping circuit 210 shown in FIG. 4. Here, the input side of the waveform shaping circuit 210 is a node A and its output side is a node B. FIG. 5B shows waveform changes at the node A and the node B.

From time t0 to time t1, a potential difference (voltage) of the potential VH—the potential VL is applied to the APD 201. When a photon enters the APD 201 at time t1, avalanche breakdown occurs in the APD 201, an avalanche breakdown current flows into the quench element 202, and the potential of the node A drops. When the voltage drop amount further increases and the potential difference applied to the APD 201 decreases, the avalanche breakdown of the APD 201 stops as shown at time t2, and the potential level of the node A does not drop any more from a predetermined value. In a period between time t2 and time t3, a current compensating for the voltage drop from the potential VL flows to the node A. At time t3, the node A is settled at the original potential level. A portion at which the output waveform exceeds a given threshold at the node A is waveform-shaped by the waveform shaping circuit 210 and output as a signal to the node B.

The arrangement of the signal lines 113, readout circuit 112, and output circuit 114 is not limited to the arrangement shown in FIG. 3. For example, each signal line 113 may be arranged to extend in the row direction (the longitudinal direction in FIG. 3), and the readout circuit 112 may be arranged at the end of the signal line 113.

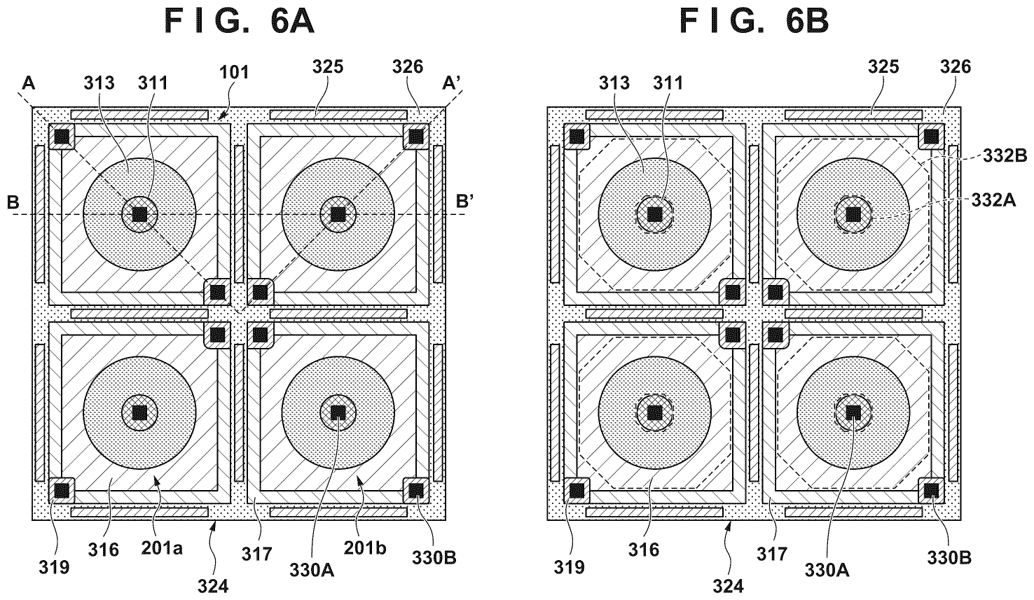

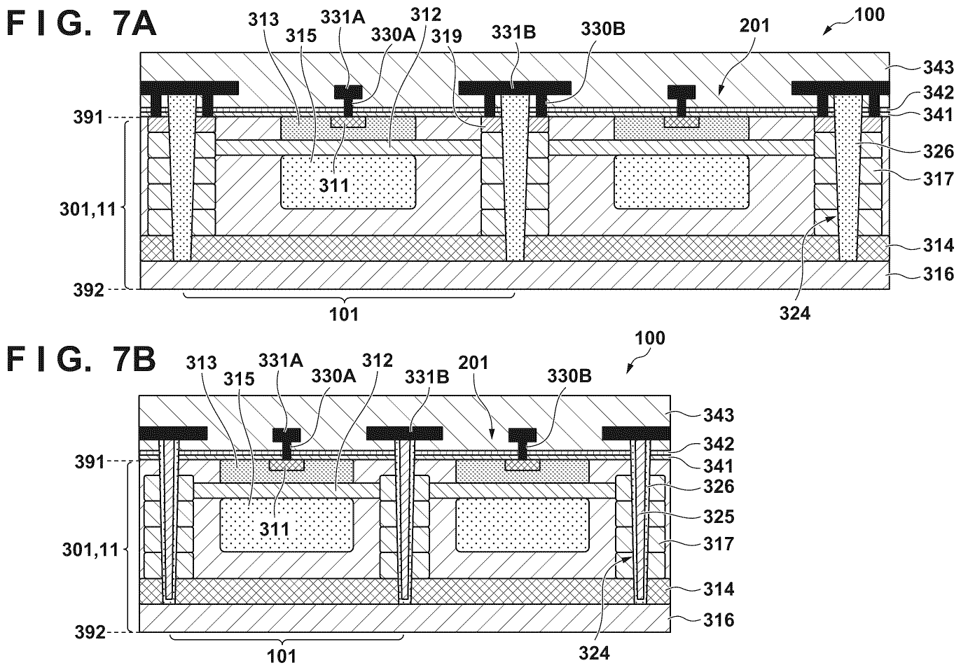

Next, the arrangement of the pixels 101 arranged in the photoelectric conversion apparatus 100 according to this embodiment will be described in detail. FIGS. 6A and 6B are plan views showing the arrangement of the pixels 101 arranged in the pixel region 12. FIG. 7A is a sectional view taken along a line A-A′ shown in FIG. 6A, and FIG. 7B is a sectional view taken along a line B-B′ shown in FIG. 6A. FIG. 6A shows a plane in the main surface 391 of the semiconductor layer 301 shown in FIGS. 7A and 7B. FIG. 6B shows an outer edge 332A of a wiring pattern 331A in the pixel 101, which is connected to a semiconductor region 311 functioning as the cathode of the APD 201, and an inner edge 332B of a wiring pattern 331B in the pixel 101, which is connected to a semiconductor region 312 functioning as the anode of the APD 201. The photoelectric conversion apparatus 100 shown in FIGS. 6A to 7B has a so-called front-illuminated type arrangement.

In the photoelectric conversion apparatus 100, the plurality of pixels 101 are arranged in the board 11 formed of a semiconductor material. Each of the plurality of pixels 101 includes the APD 201 formed in the semiconductor layer 301 provided in the board 11. It can also be said that the semiconductor layer 301 having the main surface 391 and a main surface 392 includes the APD 201. Each pixel 101 (APD 201) is isolated by a trench 324 extending from the main surface 391 of the semiconductor layer 301 toward the main surface 392.

Each pixel 101 includes the semiconductor region 311, a semiconductor region 313, a semiconductor region 315, and a semiconductor region 316 of the same conductivity type. Each pixel 101 further includes the semiconductor region 312, a semiconductor region 314, a semiconductor region 317, and a semiconductor region 319 of a conductivity type opposite to the conductivity type of the semiconductor regions 311, 313, 315, and 316. For example, the semiconductor regions 311, 313, 315, and 316 can be n-type semiconductor regions, and the semiconductor regions 312, 314, 317, and 319 can be p-type semiconductor regions. An example of the semiconductor material used for the board 11 is silicon. Accordingly, each of the semiconductor regions 311 to 317 and 319 can be a region obtained by doping an impurity corresponding to the conductivity type to silicon. For example, each of the semiconductor regions 311, 312, 313, 314, 315, 317, and 319 may be formed in the n-type semiconductor layer 301 (semiconductor region 316) using an ion implantation method or the like.

In the arrangement shown in FIGS. 7A and 7B, light enters from the upper side of the drawing. That is, in the semiconductor layer 301, the main surface 391 is the light incident surface. The n-type semiconductor region 311 is arranged in the vicinity of the main surface 391 of the semiconductor layer 301, and the n-type semiconductor region 313 is arranged around the semiconductor region 311. The p-type semiconductor region 312 is arranged at a position where it overlaps the semiconductor region 311 and the semiconductor region 313 in the orthogonal projection to the main surface 391 of the semiconductor layer 301. Hereinafter, the expression “the semiconductor region overlap” indicates that the semiconductor regions overlap in the orthogonal projection to the main surface 391 of the semiconductor layer 301. The expression “overlap” may also be used in other arrangements. The n-type semiconductor region 315 is further arranged at a position where it overlaps the semiconductor region 312, and the n-type semiconductor region 316 is arranged around the semiconductor region 315.

The semiconductor region 311 is a region having a higher n-type impurity concentration than the semiconductor region 313 and the semiconductor region 315. A p-n junction portion is formed between the p-type semiconductor region 312 and the n-type semiconductor region 311. By setting the impurity concentration of the semiconductor region 312 lower than the impurity concentration of the semiconductor region 311, a reverse bias is applied and the whole region of the semiconductor region 312 overlapping the center of the semiconductor region 311 becomes a depletion layer region. In this case, the potential difference between the semiconductor region 311 and the semiconductor region 312 is larger than the potential difference between the semiconductor region 312 and the semiconductor region 315. Further, the depletion layer region extends to a partial region of the semiconductor region 311, and a strong electric field is induced in the depletion layer region. This strong electric field induces avalanche breakdown in the depletion layer region extending to the partial region of the semiconductor region 311, and a current based on the multiplied charges is output as a signal charge. When the light having entered the pixel 101 is photoelectrically converted and avalanche breakdown is induced in the depletion layer region (avalanche breakdown region), the generated n-type charges are collected in the first semiconductor region 311.

The semiconductor region 311 is connected to the wiring pattern 331A via a contact plug 330A. The semiconductor region 312 is connected to the wiring pattern 331B via the semiconductor regions 317 and 319 and a contact plug 330B. By setting the impurity concentration of the semiconductor region 319 higher than the impurity concentration of the semiconductor region 317, the contact resistance between the semiconductor region 319 and the contact plug 330B is reduced.

In FIGS. 7A and 7B, the semiconductor region 313 and the semiconductor region 315 are formed to have similar sizes in the plane direction, but the sizes of the respective semiconductor regions are not limited thereto. For example, the semiconductor region 315 may be formed larger than the semiconductor region 313 to collect charges to the semiconductor region 311 from a larger range. The semiconductor region 313 may be not the n-type semiconductor region but a p-type semiconductor region. In this case, the impurity concentration of the semiconductor region 313 is set lower than the impurity concentration of the semiconductor region 312. If the impurity concentration of the semiconductor region 313 is too high, an avalanche breakdown region is generated between the semiconductor region 313 and the semiconductor region 311, and the Dark Count Rate (DCR) may increase.

As has been described above, each pixel 101 (APD 201) is isolated by the trench 324. In the trench 324, a plurality of conductive portions 325 are arranged apart from each other. The conductive portion 325 can be, for example, a metal such as tungsten (W), copper (Cu), or silver (Ag) embedded in the trench 324. In the conductive portion 325, a layer formed of titanium nitride (TiN), Cu-containing aluminum (AlCu), or the like may further be arranged as a barrier metal or the like. When the conductive portions 325 are arranged in the trench 324 isolating the pixels 101, even if avalanche light emission occurs during the avalanche breakdown, it is possible to suppress a crosstalk in which light is detected by the pixel 101 adjacent to the pixel 101 where the light emission occurs.

In the trench 324, the conductive portions 325 are arranged apart from each other, and an insulator 326 is arranged between the conductive portions 325 adjacent to each other. A light beam entering the pixel 101 obliquely from the normal direction of the main surface 391 of the semiconductor layer 301 can enter the trench 324. In that case, if the pixel 101 is surrounded by the conductive portion 325, the light entering the trench 324 can be partially absorbed by the conductive portion 325. On the other hand, in this embodiment, the conductive portions 325 arranged in the trench 324 are apart from each other. Therefore, absorption of the light obliquely entering the pixel 101 by the conductive portion 325 is suppressed. As a result, the sensitivity of the pixel 101 (APD 201) improves.

The wiring pattern 331B may be connected to the respective conductive portions 325 as shown in FIG. 7B. In this case, a common potential may be applied to the respective conductive portions 325. Furthermore, in this case, the same potential as the semiconductor region 312 functioning as the anode of the APD 201 to which a potential is supplied via the wiring pattern 331B may be applied to the respective conductive portions 325. This can provide an effect of reducing the DCR.

Here, a description will be given focusing on, among the APDs 201 arranged in the respective pixels 101, an APD 201a and an APD 201b arranged adjacent to each other as shown in FIG. 6A. Adjacent APDs 201 indicate two APDs 201 with no other APDs 201 arranged therebetween. At least a part of the trench 324 is arranged between the APD 201a and the APD 201b. The trench 324 further includes a portion arranged to surround the APD 201a and a portion arranged to surround the APD 201b. In this case, in the orthogonal projection to the main surface 391 of the semiconductor layer 301, the conductive portion 325 arranged between the APD 201a and the APD 201b arranged adjacent to each other may include a portion arranged between the center of the APD 201a and the center of the APD 201b. The center of the APD 201 may be the geometrical centroid position of the semiconductor region 311 or the semiconductor region 312 in the orthogonal projection to the main surface 391 of the semiconductor layer 301. There may be a case where it is difficult to discriminate the semiconductor regions 311 to 317 and 319. In that case, the center of the APD 201 may be the geometrical centroid position of the semiconductor region surrounded by the trench 324 in the orthogonal projection to the main surface 391 of the semiconductor layer 301.

As shown FIG. 6A, in the orthogonal projection to the main surface 391 of the semiconductor layer 301, the portion of the trench 324 arranged to surround the APD 201a and the portion thereof arranged to surround 201b may have polygonal shapes sharing one side. In this case, the conductive portion 325 may be arranged in the shared side of the polygonal shape so as to intersect a virtual line connecting the center of the APD 201a and the center of the APD 201b. Further, as shown in FIG. 6A, only one conductive portion 325 may be arranged in the shared side, and other conductive portions 325 may not be arranged therein. However, the present invention is not limited to this, and two or more conductive portions 325 may be arranged apart from each other in one side of the trench 324 surrounding the APDs 201a and 201b.

In the arrangement shown in FIGS. 6A, 7A, and 7B, each conductive portion 325 is arranged in the side portion of the polygonal shape of the trench 324 surrounding the APDs 201 so as to intersect the virtual line connecting the centers of the adjacent APDs 201. No conductor portion 325 is arranged at positions including the vertices of the polygonal shape of the trench 324 surrounding the APD 201. The side portion of the polygonal shape of the trench 324 surrounding the APDs 201 is close to the centers of the adjacent APDs 201. On the other hand, the distances from the vertex portion of the polygonal shape to the centers of the adjacent APDs 201 are larger than that for the side portion. That is, if avalanche light emission occurs in a given APD 201, the light passing through the side portion of the polygonal shape will enter the adjacent APD 201 with less attenuation than the light passing through the vertex of the polygonal shape. Accordingly, by arranging the conductive portions 325 in the side portions of the polygonal shape of the trench 324 but not in the vertex portions, both suppression of a crosstalk and suppression of absorption of the light obliquely entering the pixel 101 can be achieved.

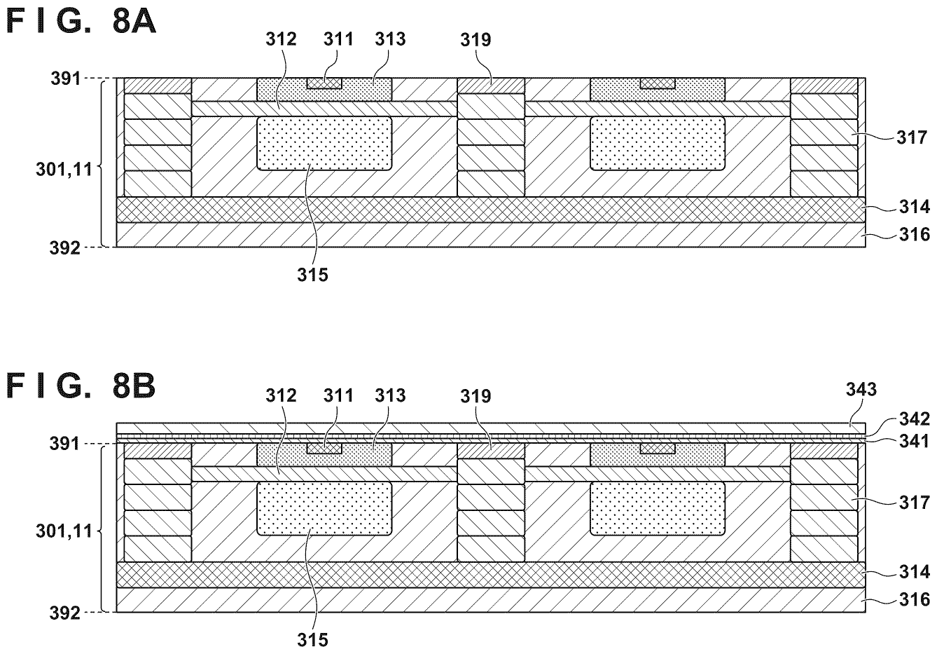

Next, with reference to FIGS. 8A to 11B, a manufacturing step (manufacturing method) of the photoelectric conversion apparatus 100 shown in FIGS. 6A, 7A, and 7B will be described. First, as shown in FIG. 8A, the semiconductor regions 311 to 317 and 319 are formed in the semiconductor layer 301. For example, with respect to the semiconductor layer 301 including the semiconductor region 316 as an epitaxial layer having an appropriate n-type impurity concentration, the semiconductor regions 311 to 315, 317, and 319 as diffusion regions may be formed using an ion implantation method or the like.

Next, as shown in FIG. 8B, an insulating layer 341, a protection layer 342, and a part of an interlayer insulating layer 343 are formed. For example, silicon oxide or the like is used for the insulating layer 341. The protection layer 342 is arranged to prevent a plasma damage in a subsequent etching step and the like and contamination caused by metals used for the contact plugs 330, the wiring patterns 331, and the like. For example, silicon nitride, silicon oxynitride, silicon carbide, or the like can be used for the protection layer 342. For the interlayer insulating layer 343, silicon oxide, silicon nitride, silicon oxynitride, or the like can be used. For the interlayer insulating layer 343, an appropriate material not limited to an inorganic material but also including an organic material may be used in accordance with the materials used for the contact plugs 330, the wiring patterns 331, and the like formed in subsequent steps.

After a part of the interlayer insulating layer 343 is formed, as shown in FIG. 9A, the trench 324 is formed. For example, first, after forming a mask pattern on the interlayer insulating layer 343, the interlayer insulating layer 343, the protection layer 342, and the insulating layer 341 are etched. Then, the semiconductor layer 301 may be etched. This is because the etching conditions of the materials used for the interlayer insulating layer 343, the protection layer 342, and the insulating layer 341 can be different from the etching condition of silicon used for the semiconductor layer 301. However, the present invention is not limited to this, and etching may be continuously performed from the interlayer insulating layer 343 to the semiconductor layer 301 in accordance with the etching conditions. Alternatively, for example, the trench 324 may be formed before forming the insulating layer 341, the protection layer 342, and the interlayer insulating layer 343, and then the insulating layer 341, the protection layer 342, and the interlayer insulating layer 343 may be formed.

The trench 324 is etched from the main surface 391 of the semiconductor layer 301 toward the main surface 392. The trench 324 may extend through the semiconductor region 314 as shown in FIG. 9A, or the bottom (the end portion on the side of the main surface 392 of the semiconductor layer 301) of the trench 324 may be located in the semiconductor region 314. Alternatively, the bottom of the trench 324 may be located in the semiconductor region 317. In the depth direction as the direction connecting the main surface 391 and the main surface 392, the trench 324 is formed such that the conductive portion 325 is formed to at least the depth where the semiconductor region 312 is arranged. As has been described above, avalanche breakdown is induced in the depletion layer region formed to extend from the semiconductor region 312 to a partial region of the semiconductor region 311. Thus, avalanche light emission occurs in the depletion layer region. When the conductive portion 325 is formed from the main surface 391 of the semiconductor layer 301 to the depth where the semiconductor region 312 is arranged, a crosstalk caused by avalanche light emission can be suppressed.

After the trench 324 is formed, the insulator 326 is embedded in the trench 324 as shown in FIG. 9B. The insulator 326 may be fully embedded in the trench 324, or may have some voids. Silicon oxide, silicon nitride, or the like can be used for the insulator 326. For example, the insulator 326 may be formed of one material such as silicon oxide. Alternatively, for example, by taking into consideration the next formation of the conductive portions 325, the insulator 326 may be formed from a plurality of insulating layers. More specifically, the insulator 326 may include an insulating layer using, for example, silicon oxide, and an insulating layer arranged between the insulating layer using silicon oxide and the inner wall of the trench 324 and containing a material different from silicon oxide, for example, using silicon nitride. By etching the insulating layer using silicon oxide while using the insulating layer using silicon nitride as an etch stopper, trenches for embedding the conductive portions 325 can be formed. An insulating layer using silicon oxide may be further arranged between the insulating layer using silicon nitride and the inner wall of the trench 324. When silicon oxide is arranged in the interface between the semiconductor layer 301 and the insulator 326, the density of interface state decreases and noise is suppressed as compared to a case where silicon nitride is arranged in the interface. So far, FIGS. 8A to 9B show the section taken along the line A-A′ shown in FIG. 6A.

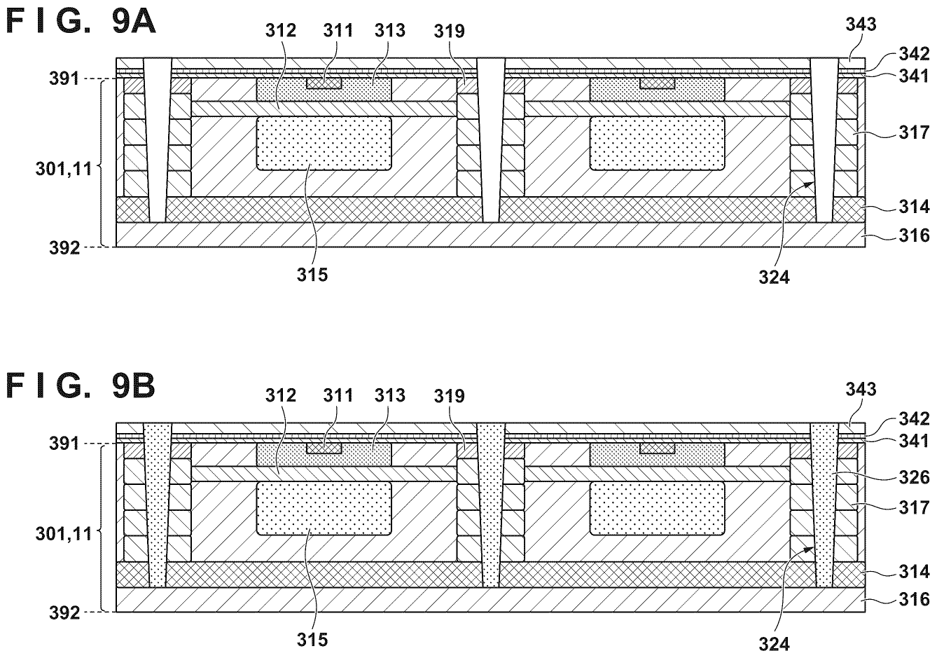

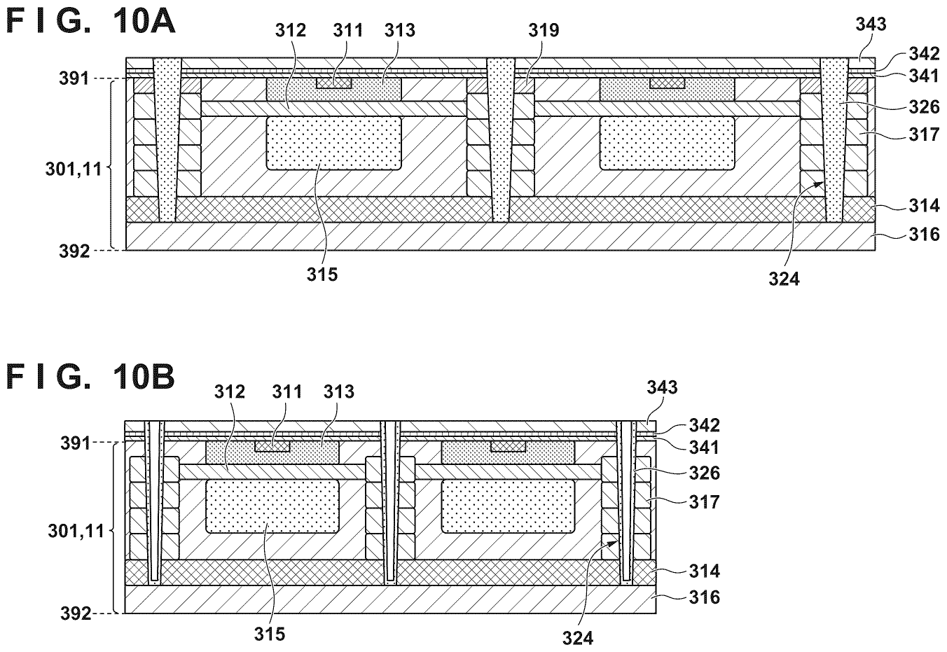

Then, as shown in FIGS. 10A and 10B, trenches are formed in the portions of the insulator 326 where the conductive portions 325 are to be formed. FIG. 10A shows the section taken along the line A-A′ shown in FIG. 6A, and FIG. 10B shows the section taken along the line B-B′ shown in FIG. 6A. The sections respectively taken along the line A-A′ and the line B-B′ shown in FIG. 6A will also be shown in the following steps.

Since the plurality of conductive portions 325 are arranged apart from each other as described above, trenches are formed in some portions of the insulator 326 embedded in the trench 324. For example, the portions shown in FIG. 10A are protected by a mask pattern so trenches for embedding the conductive portions 325 are not formed.

As shown in FIG. 10B, a part of insulating layers of the insulator 326 can remain in the trench for embedding the conductive portion 325 as described above. For example, if the insulator 326 is formed from silicon oxide (for embedding)/silicon nitride (for the etch stopper)/silicon oxide (for forming the interface with the semiconductor layer 301), the silicon oxide layer for forming the interface with the semiconductor layer 301 may remain. In this case, by taking into consideration that the conductive portion 325 is applied with the same potential as the semiconductor region 312 functioning as the anode of the APD 201, the thickness of the remaining silicon oxide can be about 0.1 μm to 0.15 μm.

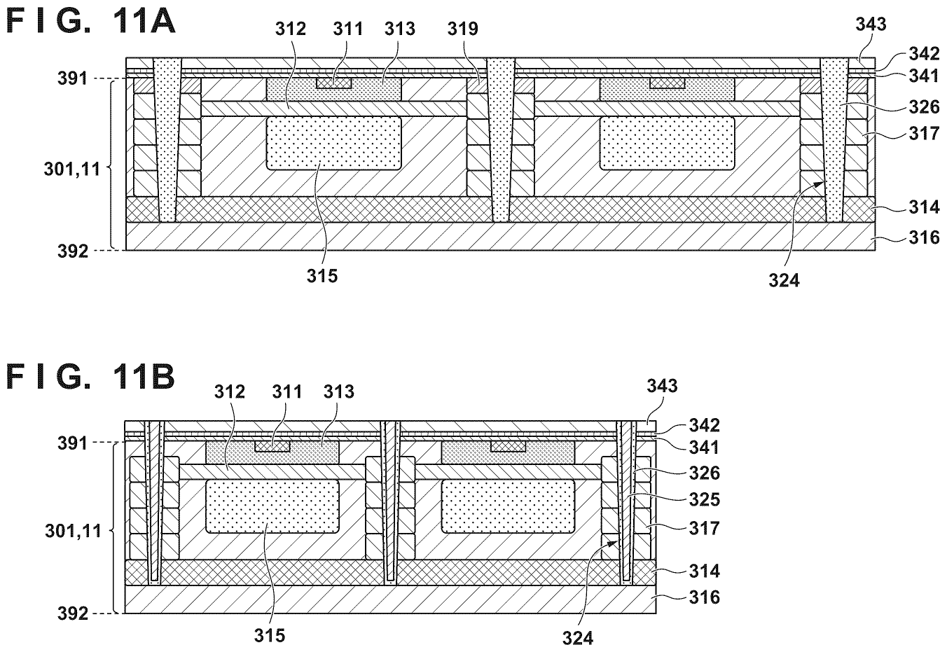

After the trenches for embedding the conductive portions 325 are formed, the conductive portions 325 are embedded in the trenches as shown in FIGS. 11A and 11B. As has been described above, W, Cu, Ag, or the like can be used for the conductive portion 325. A barrier metal (for example, TiN, Tantalum Nitride (TaN), AlCu, or the like) for W, Cu, Ag, or the like may further be arranged. In the trench for embedding the conductive portion 325, if a part of insulating layers of the insulator 326 remains as described above, this part of insulating layers forming the insulator 326 is arranged between the inner wall of the trench 324 and the conductive portion 325.

After the conductive portions 325 and the insulator 326 are formed in the trench 324, the contact plugs 330, the wiring patterns 331, and the remaining portion of the interlayer insulating layer 343 are formed. Thus, the photoelectric conversion apparatus 100 shown in FIGS. 6A, 7A, and 7B is formed. Although not shown in FIGS. 7A and 7B, a color filter, a microlens, or the like may be arranged on the interlayer insulating layer 343.

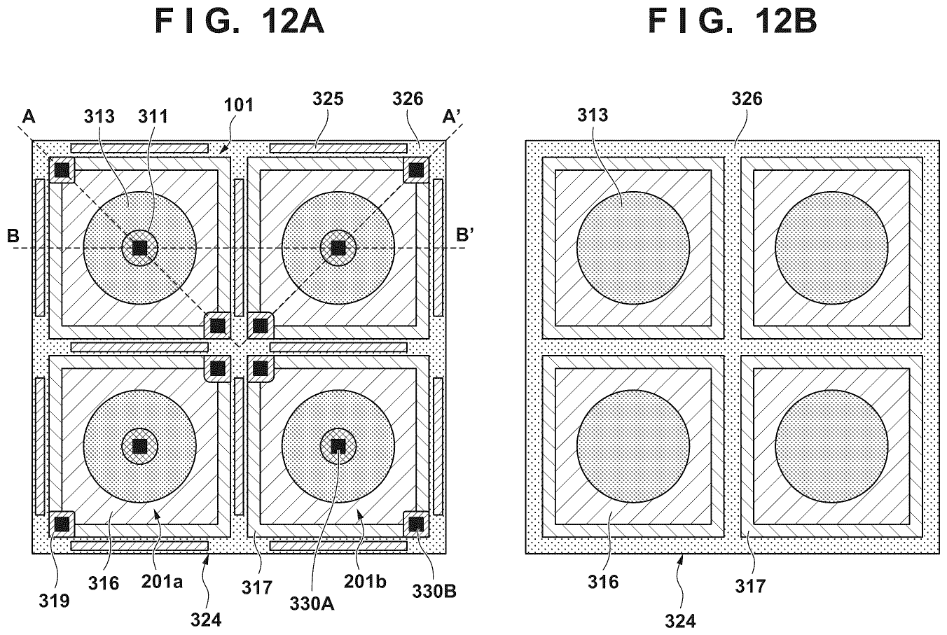

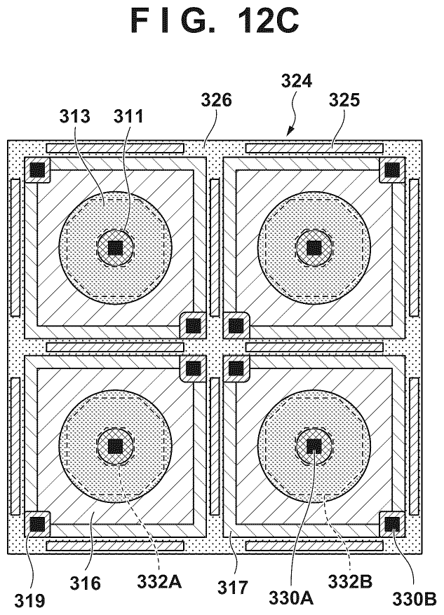

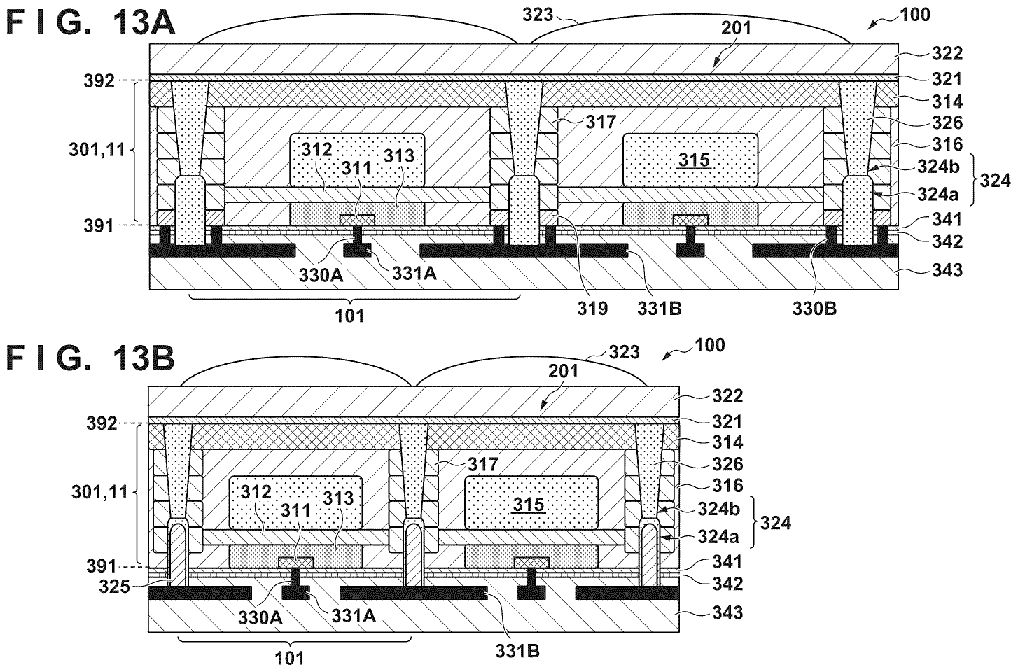

Next, with reference to FIGS. 12A to 13B, an arrangement different from the above-described arrangement of the pixels 101 arranged in the photoelectric conversion apparatus 100 according to this embodiment will be described. In the above description, the photoelectric conversion apparatus 100 has a so-called front-illuminated type arrangement. On the other hand, the photoelectric conversion apparatus 100 shown in FIGS. 12A to 13B has a so-called back-illuminated type arrangement in which light enters from the main surface 392 of the semiconductor layer 301. Differences from the above-described front-illuminated type arrangement will be mainly described below, and a description of the similar arrangement will be omitted, as appropriate. For example, the relationship among the conductive types and impurity concentrations of the semiconductor regions 311 to 317 and 319 may be similar to that in the front-illuminated type arrangement, so that a description thereof will be omitted here.

FIGS. 12A to 12C are plan views showing the arrangement of the pixels 101 arranged in the pixel region 12. FIG. 13A is a sectional view taken along a line A-A′ shown in FIG. 12A, and FIG. 13B is a sectional view taken along a line B-B′ shown in FIG. 12A. FIG. 12A shows a plane in the main surface 391 of the semiconductor layer 301 shown in FIGS. 13A and 13B. FIG. 12B shows the arrangement of the semiconductor regions in the orthogonal projection from the main surface 392 of the semiconductor layer 301 shown in FIGS. 13A and 13B. FIG. 12C shows the outer edge 332A of the wiring pattern 331A in the pixel 101, which is connected to the semiconductor region 311 functioning as the cathode of the APD 201, and the inner edge 332B of the wiring pattern 331B in the pixel 101, which is connected to the semiconductor region 312 functioning as the anode of the APD 201.

As shown in FIG. 12C, the region between the outer edge 332A of the wiring pattern 331A and the inner edge 332B of the wiring pattern 331B is narrower than in FIG. 6A showing the front-illuminated type photoelectric conversion apparatus 100. In the front-illuminated type arrangement, light enters the semiconductor layer 301 after passing through the region between the outer edge 332A of the wiring pattern 331A and the inner edge 332B of the wiring pattern 331B. Accordingly, it is necessary to design a wide region between the outer edge 332A of the wiring pattern 331A and the inner edge 332B of the wiring pattern 331B. On the other hand, in the back-illuminated type arrangement, light having passed through the semiconductor layer 301 is reflected to the semiconductor layer 301, and this can improve the sensitivity of the pixel 101 (APD 201). Therefore, in order to reflect more light having passed through the semiconductor layer 301, the region between the outer edge 332A of the wiring pattern 331A and the inner edge 332B of the wiring pattern 331B is narrower than in the arrangement shown in FIG. 6B showing the front-illuminated type photoelectric conversion apparatus 100.

Next, with reference to FIGS. 13A and 13B, the arrangement different from the above-described arrangement shown in FIGS. 7A and 7B will be mainly described. The semiconductor layer 301 shown in FIGS. 13A and 13B is vertically reversed from the semiconductor layer 301 shown in FIGS. 7A and 7B. This is because FIGS. 13A and 13B show the arrangement in which light enters from the upper side of the drawing, as in FIGS. 7A and 7B.

In the arrangement shown in FIGS. 13A and 13B, the trench 324 includes a portion 324a arranged to extend from the main surface 391 of the semiconductor layer 301 toward the main surface 392, and a portion 324b arranged between the portion 324a and the main surface 392 of the semiconductor layer 301. In this case, a step is generated in the connection portion between the portion 324a and the portion 324b of the trench 324. The portion 324a and the portion 324b of the trench 324 will be described using the manufacturing step (manufacturing method) to be described later.

Furthermore, in the arrangement shown in FIGS. 7A and 7B, a partial region of the semiconductor region 316 is arranged between the semiconductor region 314 and the main surface 392 of the semiconductor layer 301. On the other hand, in the back-illuminated type photoelectric conversion apparatus 100 shown in FIGS. 13A and 13B, the main surface 392 of the semiconductor layer 301 is formed by the semiconductor region 314, and the semiconductor layer 301 is thinner than in the arrangement shown in FIGS. 7A and 7B. Further, in the arrangement shown in FIGS. 13A and 13B, a pinning layer 321, a planarized layer 322, and a microlens 323 are arranged on the main surface 392 of the semiconductor layer 301. When the pinning layer 321 is arranged in contact with the main surface 392 of the semiconductor layer 301, holes are induced in the vicinity of the main surface 392 of the semiconductor layer 301, and a dark current is suppressed. For the pinning layer 321, hafnium oxide, zirconium oxide, aluminum oxide, titanium oxide, tantalum oxide, or the like can be used. The planarized layer 322 arranged between the pinning layer 321 and the microlens 323 is a layer for planarizing the surface on which the microlens 323 is arranged. The planarized layer 322 may be formed of an inorganic material or an organic material such as a resin. The planarized layer 322 may have a stacked structure obtained by stacking a plurality of material layers. The microlens 323 can be formed using a resin material or the like. A color filter may be arranged between the pinning layer 321 and the planarized layer 322 or between the planarized layer 322 and the microlens 323. Alternatively, the planarized layer 322 may function as a color filter.

As shown in FIG. 13B, unlike the arrangement shown in FIG. 7B, the conductive portion 325 is not formed from the main surface 391 of the semiconductor layer 301 to the semiconductor region 314 but formed from the main surface 391 of the semiconductor layer 301 to the position beyond the depth where the semiconductor region 312 is arranged. As has been described above, avalanche light emission is highly likely to occur in the depletion layer region formed to extend from the semiconductor region 312 to a partial region of the semiconductor region 311. Therefore, the conductive portion 325 need only be formed from the main surface 391 of the semiconductor layer 301 to at least the depth where the semiconductor region 312 is arranged.

As shown in FIG. 12A, the plurality of conductive portions 325 are arranged apart from each other, as in the arrangement shown in FIG. 6A. With this arrangement, as has been described above, it is possible to improve the sensitivity while suppressing a crosstalk as compared to the case where the APD 201 is surrounded by the conductive portion 325. Further, as shown in FIG. 13B, the depth where the conductive portion 325 is arranged is shallower. With this, light obliquely entering the pixel 101 is less likely to be absorbed by the conductive portion 325. Furthermore, as shown in FIGS. 13A and 13B, the portion 324b of the trench 324 has a tapered shape with the width decreasing from the main surface 392 of the semiconductor layer 301 toward the main surface 391. With this, when light obliquely entering the pixel 101 is reflected at the interface between the semiconductor layer 301 and the insulator 326 embedded in the trench 324, the reflected light is more likely to be directed toward the depletion layer region extending from the semiconductor region 312 to the semiconductor region 311. That is, it is possible to further improve the sensitivity of the pixel 101 (APD 201) while suppressing a crosstalk.

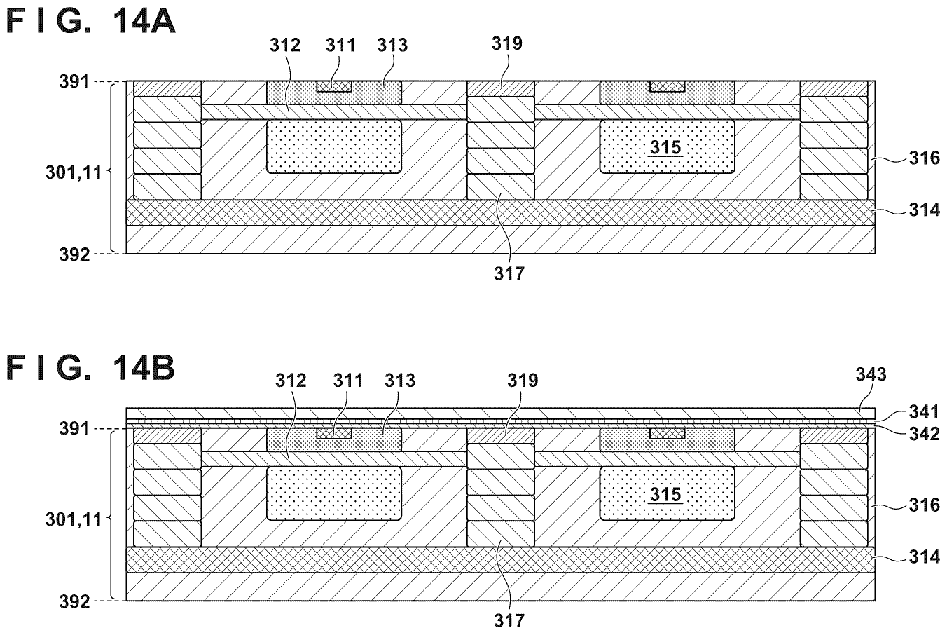

Next, with reference to FIGS. 14A to 21B, a manufacturing step (manufacturing method) of the photoelectric conversion apparatus 100 shown in FIGS. 12A to 13B will be described. The step shown in FIG. 14A may be similar to the step shown in FIG. 8A described above. As shown in FIG. 14A, the semiconductor regions 311 to 317 and 319 are formed in the semiconductor layer 301 using ion implantation or the like. Then, as shown in FIG. 14B, the insulating layer 341, the protection layer 342, and a part of the interlayer insulating layer 343 are formed. The step shown in FIG. 14B may be similar to the step shown in FIG. 8B described above.

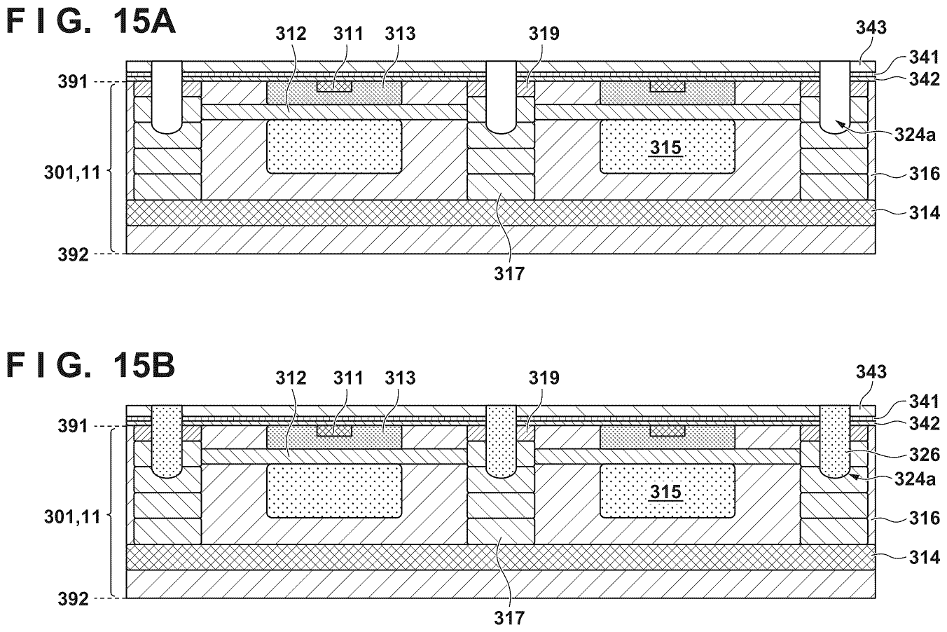

After the insulating layer 341, the protection layer 342, and a part of the interlayer insulating layer 343 are formed, as shown in FIG. 15A, the portion 324a of the trench 324 is formed from the main surface 391 of the semiconductor layer 301 toward the main surface 392. The portion 324a of the trench 324 is formed such that the conductive portion 325 is formed to at least the depth where the semiconductor region 312 is arranged. In other words, the portion 324a of the trench 324 is formed to extend through the semiconductor region 312 in the depth direction as the direction connecting the main surface 391 and the main surface 392 of the semiconductor layer 301. Since the portion 324a of the trench 324 is formed by etching the semiconductor layer 301 of, for example, silicon, the bottom of the portion 324a may have a rounded shape as shown in FIG. 15A.

After the portion 324a of the trench 324 is formed, the insulator 326 is embedded in the portion 324a of the trench 324 as shown in FIG. 15B. The insulator 326 may be fully embedded in the portion 324a of the trench 324, or may have some voids. The insulator 326 may be formed of one material, or may be formed from a plurality of insulating layers as described above. So far, FIGS. 14A to 15B show the section taken along the line A-A′ shown in FIG. 12A.

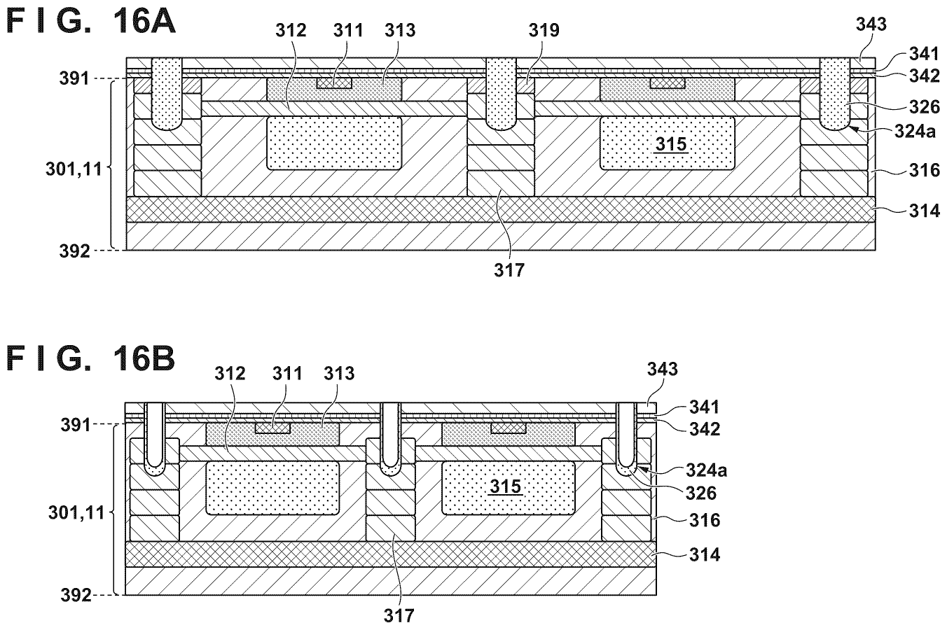

Then, as shown in FIGS. 16A and 16B, trenches are formed in the portions of the insulator 326 where the conductive portions 325 are to be formed. FIG. 16A shows the section taken along the line A-A′ shown in FIG. 12A, and FIG. 16B shows the section taken along the line B-B′ shown in FIG. 12A. The sections respectively taken along the line A-A′ and the line B-B′ shown in FIG. 12A will also be shown in the following steps.

Since the plurality of conductive portions 325 are arranged apart from each other as described above, trenches are formed in some portions of the insulator 326 embedded in the trench 324. For example, trenches for embedding the conductive portions 325 are not formed in the portions shown in FIG. 16A. As shown in FIG. 16B, a part of insulators (insulating layers) of the insulator 326 can remain in the trench for embedding the conductive portion 325.

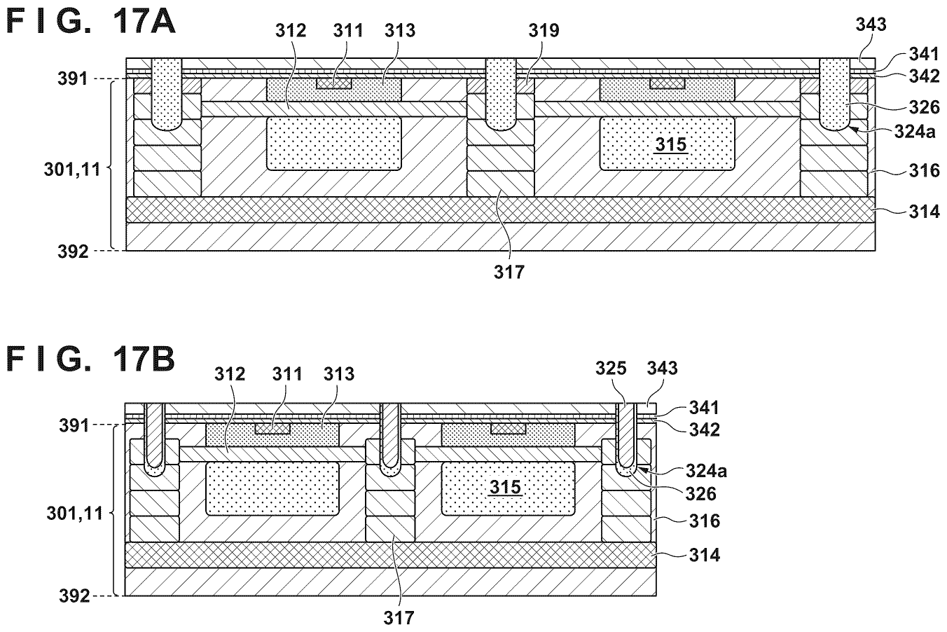

After the trenches for embedding the conductive portions 325 are formed, the conductive portions 325 are embedded in the trenches as shown in FIGS. 17A and 17B. W, Cu, or Ag, and a barrier metal (for example, TiN, TaN, AlCu, or the like) therefor are embedded as the conductive portion 325.

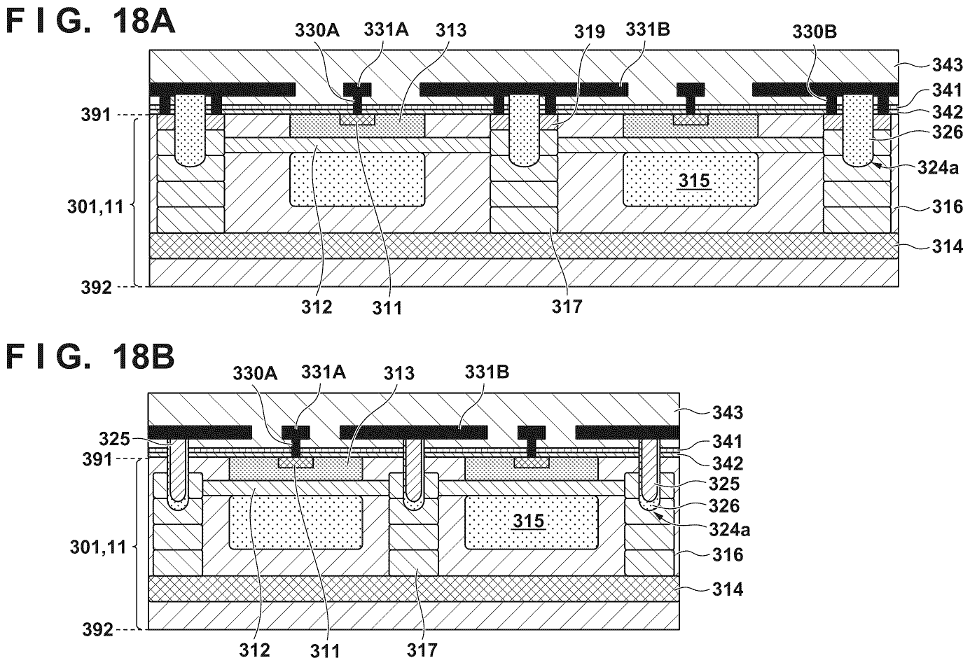

After the conductive portions 325 and the insulator 326 are formed in the trench 324, the contact plugs 330, the wiring patterns 331, and the remaining portion of the interlayer insulating layer 343 are formed as shown in FIGS. 18A and 18B. The steps so far can be executed using methods similar to those in the steps shown in FIGS. 8A to 11B described above, except that only the partial portion 324a of the trench 324 has been formed.

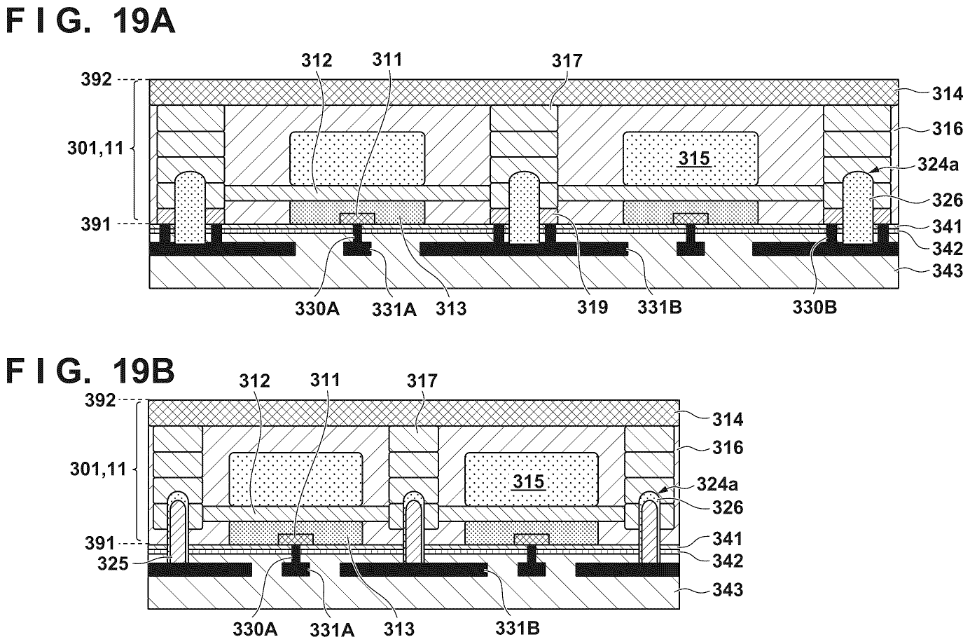

Then, as shown in FIGS. 19A and 19B, the semiconductor layer 301 is thinned until the semiconductor region 314 is exposed as the main surface 392 of the semiconductor layer 301. The semiconductor layer 301 can be thinned using, for example, a chemical mechanical polishing (CMP) method or an etch back method. Before thinning the semiconductor layer 301, the semiconductor layer 301 can be bonded to a support substrate (not shown) via the interlayer insulating layer 343 or the like. The semiconductor layer 301 shown in the steps in FIGS. 19A and 19B and subsequent drawings is vertically reversed from that in the steps in FIGS. 18A and 18B and the preceding steps.

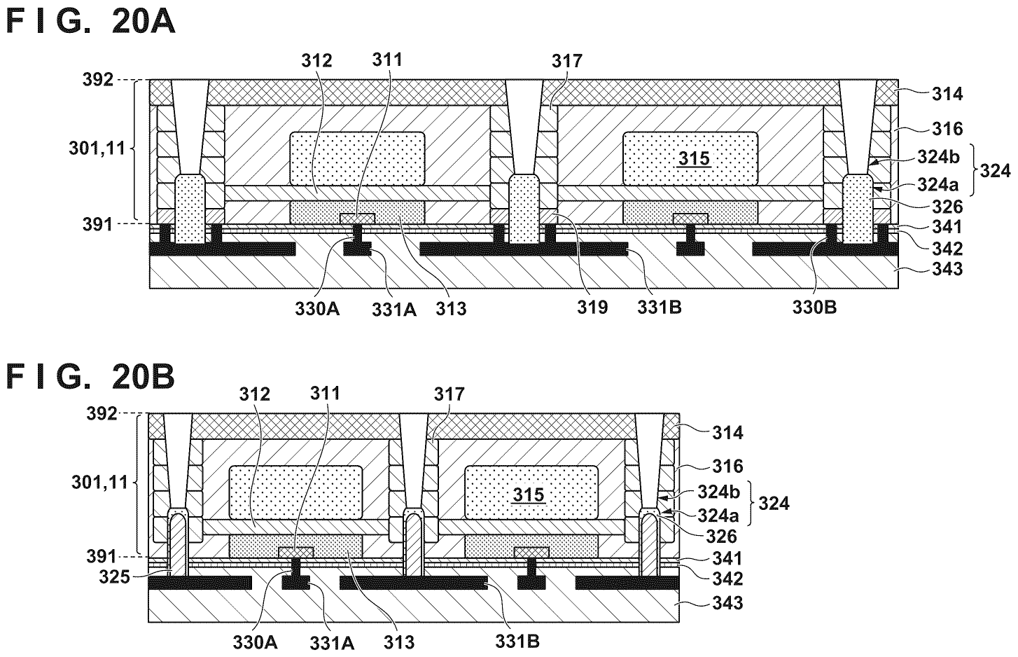

After the semiconductor layer 301 is thinned, the portion 324b of the trench 324 is formed as shown in FIGS. 20A and 20B. The portion 324b of the trench 324 is etched from the main surface 392 of the semiconductor layer 301 toward the main surface 391. As has been described above, the portion 324b of the trench 324 may be formed to have a tapered shape with the width decreasing from the main surface 392 of the semiconductor layer 301 toward the main surface 391. In this case, the portion 324a and the portion 324b can be designed such that the width of the portion 324a is larger than the width of the portion 324b in the connection portion between the portion 324a and the portion 324b of the trench 324. Accordingly, a step is generated in the connection portion between the portion 324a and the portion 324b of the trench 324. In addition, the width of the portion 324a is larger than the width of the portion 324b in the connection portion between the portion 324a and the portion 324b of the trench 324. Therefore, when forming the portion 324b which is formed after the portion 324a of the trench 324, even if an alignment shift or the like occurs, the portion 324a and the portion 324b are easily connected.

When forming the trench 324, the portion 324a etched from the main surface 391 of the semiconductor layer 301 toward the main surface 392 and the portion 324b etched from the main surface 392 toward the main surface 391 are connected to each other. Therefore, the trench 324 has a structure extending through the semiconductor layer 301.

The portion 324b of the trench 324 may not have the tapered shape. Even if the portion 324b of the trench 324 does not have the tapered shape, the portion 324a and the portion 324b may be designed such that the width of the portion 324a is larger than the width of the portion 324b. With this, even if an alignment shift or the like occurs, the portion 324a and the portion 324b are easily connected to each other.

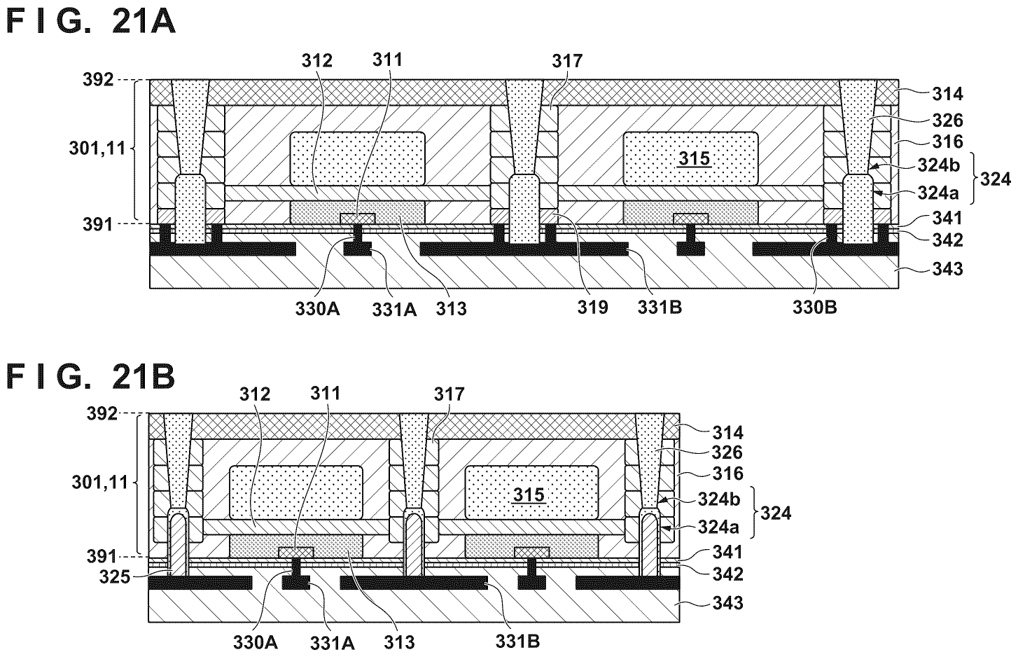

After the portion 324b of the trench 324 is formed, the insulator 326 is embedded in the portion 324b of the trench 324 as shown in FIGS. 21A and 21B. The insulator 326 may be fully embedded in the portion 324b of the trench 324, or may have some voids. The portion of the insulator 326 embedded in the portion 324a of the trench 324 may be different in arrangement from the portion of the insulator 326 embedded in the portion 324b of the trench 324. For example, the portion of the insulator 326 embedded in the portion 324a of the trench 324 may have the multilayered structure as described above, and the portion of the insulator 326 embedded in the portion 324b of the trench 324 may be formed of one material.

The portion of the insulator 326 embedded in the portion 324b of the trench 324 is not limited to silicon oxide or silicon nitride as described above. For example, aluminum oxide or tantalum oxide may be embedded. Further, for example, a resin containing white particles such as titanium oxide may be embedded as the insulator 326. If aluminum oxide is embedded in the portion 324b of the trench 324, the portion of the insulator 326 embedded in the portion 324b of the trench 324 functions similarly to the pinning layer 321. If tantalum oxide is embedded as the insulator 326 in the portion 324b of the trench 324, the portion 324b can function as an anti-reflection film that suppresses stray light between the pixels 101. If a resin including white particles such as titanium oxide is embedded as the insulator 326 in the portion 324b of the trench 324, the insulator 326 can function as a reflecting member that reflects not only the light having entered the interface between the semiconductor layer 301 and the insulator 326 but the light having entered the insulator 326. A reflecting member not limited to the resin containing white particles such as titanium oxide but using a material having a higher reflectivity than the conductive portion 325 may be arranged in the portion 324b of the trench 324. The reflecting member may be, for example, a metal (for example, a metal layer) of aluminum or the like. In this case, the portion of the insulator 326 embedded in the portion 324b of the trench 324 may have a stacked structure of the insulator 326 and the reflecting member.

After embedding the portion 324b of the trench 324 with the insulator 326, the pinning layer 321, the planarized layer 322, the microlens 323, and the like are formed. Thus, the photoelectric conversion apparatus 100 shown in FIGS. 13A to 14B is formed. In the photoelectric conversion apparatus 100 shown in FIGS. 13A to 14B, the conductive portions 325 are arranged in the portion 324a of the trench 324 but not arranged in the portion 324b. With this arrangement, as has been described above, absorption of the light obliquely entering the pixel 101 by the conductive portion 325 is suppressed. As a result, it is possible to further improve the sensitivity of the pixel 101 (APD 201) while suppressing a crosstalk.

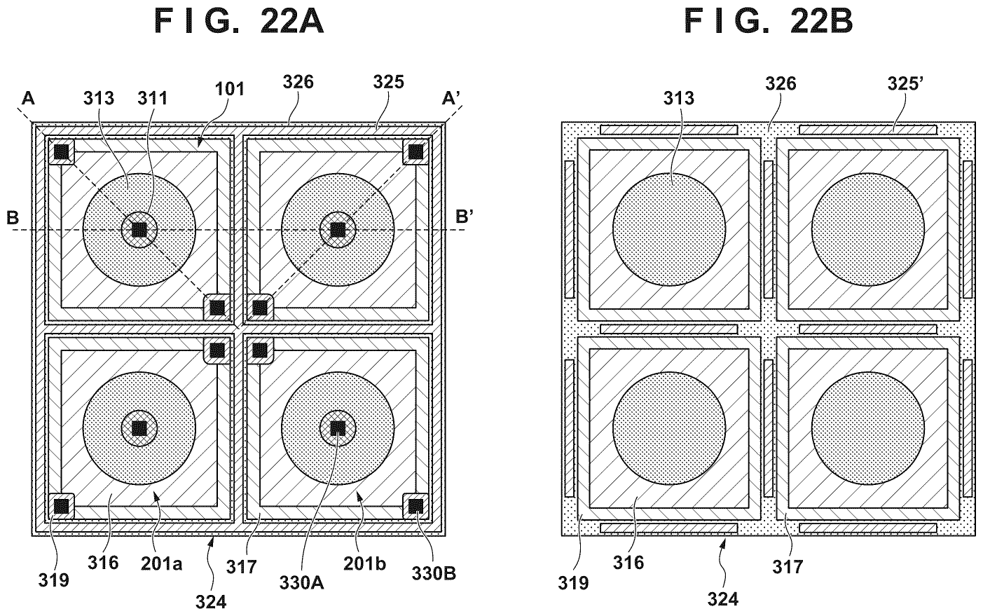

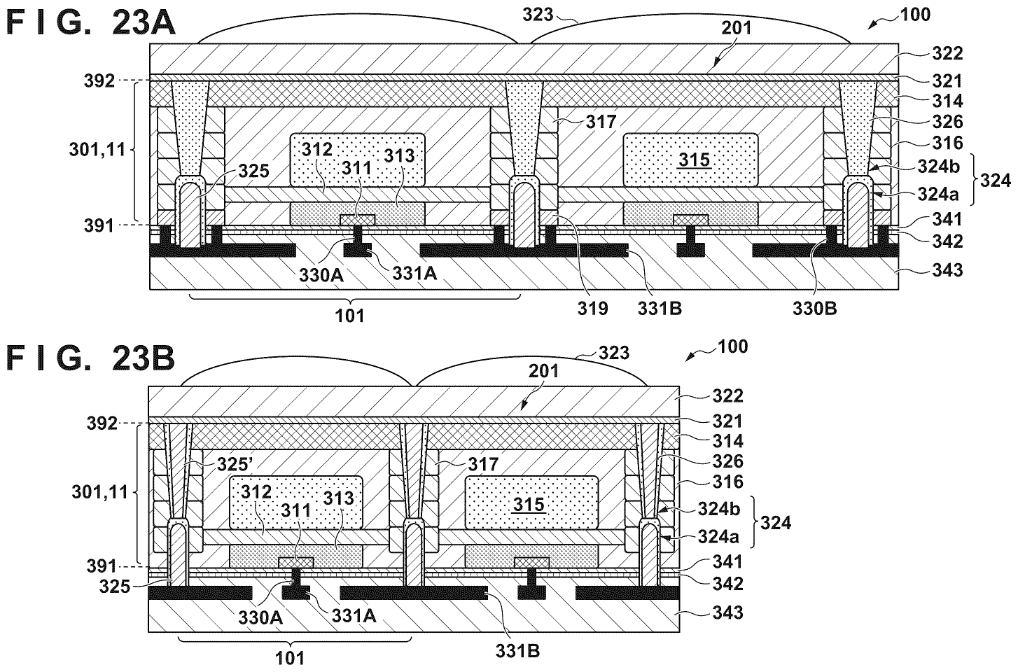

FIGS. 22A to 23B are views showing a modification of the photoelectric conversion apparatus 100 shown in FIGS. 12A to 13B. FIGS. 22A and 22B are plan views showing the arrangement of the pixels 101 arranged in the pixel region 12. FIG. 23A is a sectional view taken along a line A-A′ shown in FIG. 22A, and FIG. 23B is a sectional view taken along a line B-B′ shown in FIG. 22A. FIG. 22A shows a plane in the main surface 391 of the semiconductor layer 301 shown in FIGS. 23A and 23B. FIG. 22B shows the arrangement of the semiconductor regions in the orthogonal projection from the main surface 392 of the semiconductor layer 301 shown in FIGS. 23A and 23B.

In the arrangement shown in FIGS. 22A to 23B, a plurality of conductive portions 325′ are arranged apart from each other in the portion 324b of the trench 324. The conductive portion 325 arranged in the portion 324a of the trench 324 is arranged over the entire portion 324a. That is, each APD 201 is continuously surrounded by the conductive portion 325. Since the APD 201 is surrounded by the conductive portion 325 arranged in the portion 324a of the trench 324, the effect of suppressing a crosstalk between the pixels 101 caused by avalanche light emission is further improved. In addition, since the conductive portions 325′ are arranged in the portion 324b of the trench 324, a crosstalk caused by avalanche light emission is also suppressed in the portion 324b of the trench 324. Since the conductive portions 325′ are arranged apart from each other in the portion 324b of the trench 324, the sensitivity of the pixel 101 (APD 201) improves as compared to a case where the semiconductor portion 325′ is arranged to surround the APD 201.

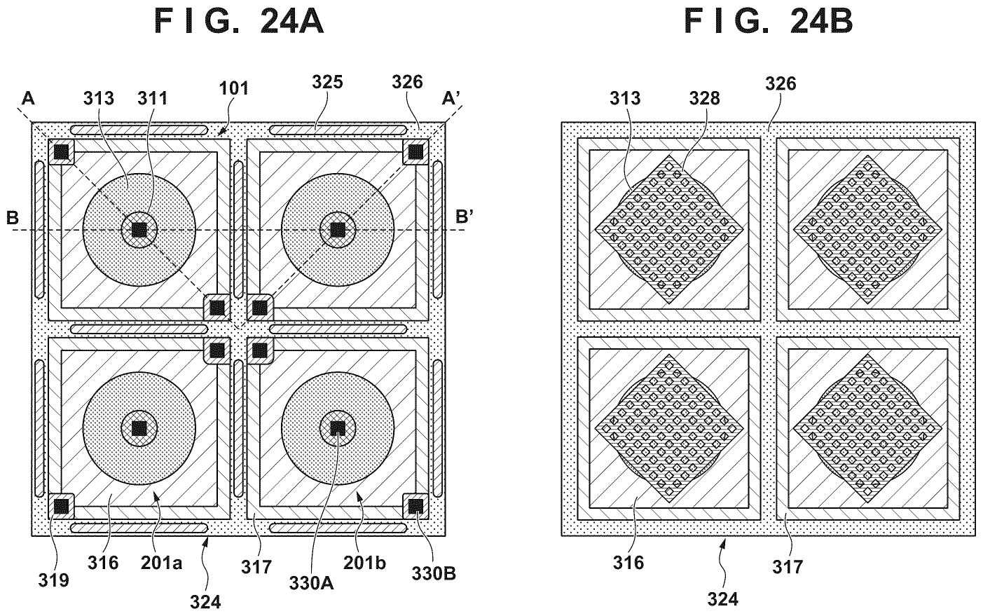

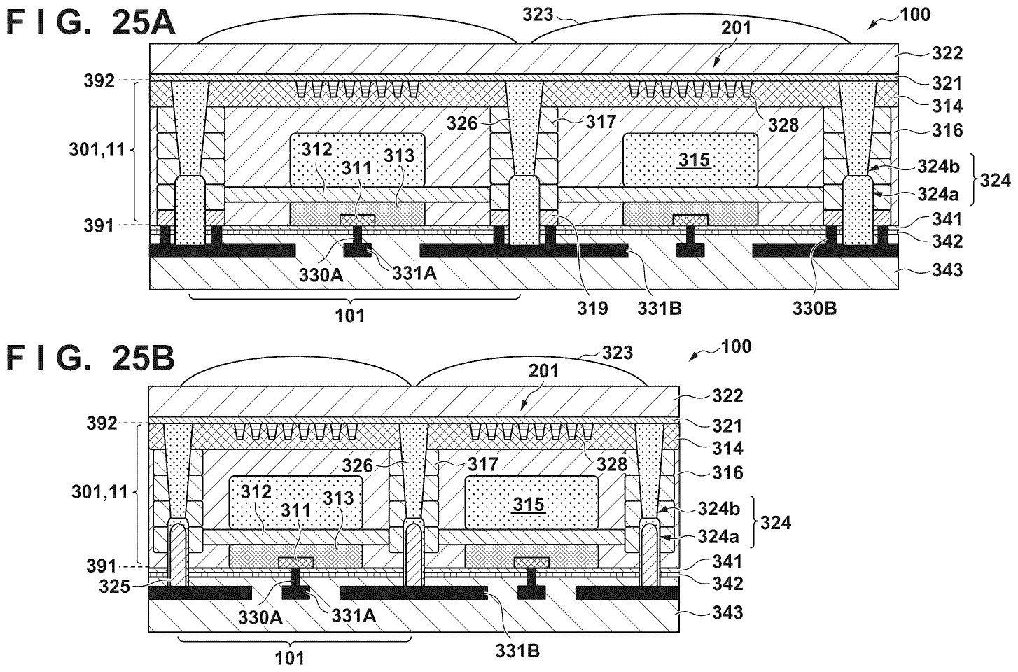

FIGS. 24A to 25B are views showing a modification of the photoelectric conversion apparatus 100 shown in FIGS. 12A to 13B. FIGS. 24A and 24B are plan views showing the arrangement of the pixels 101 arranged in the pixel region 12. FIG. 25A is a sectional view taken along a line A-A′ shown in FIG. 24A, and FIG. 25B is a sectional view taken along a line B-B′ shown in FIG. 24A. FIG. 24A shows a plane in the main surface 391 of the semiconductor layer 301 shown in FIGS. 25A and 25B. FIG. 24B shows the arrangement of the semiconductor regions in the orthogonal projection from the main surface 392 of the semiconductor layer 301 shown in FIGS. 25A and 25B.

In the arrangement shown in FIGS. 22A to 23B, a scattering diffraction structure 328 is arranged in the surface 392 of the semiconductor layer 301 so as to at least partially overlap the APD 201. The scattering diffraction structure 328 is formed by forming trenches in the main surface 392 of the semiconductor layer 301 and embedding an appropriate material in the trenches. For example, a material similar to the insulator 326 embedded in the portion 324b of the trench 324 may be embedded in the trenches for the scattering diffraction structure 328. For example, silicon oxide or silicon nitride may be embedded in the trenches for the scattering diffraction structure 328, or an organic material such as a resin or a metal may be embedded therein. The trenches for the scattering diffraction structure 328 can be formed to have a depth of, for example, about 1 μm to 0.6 μm from the main surface 392 of the semiconductor layer 301. In order to achieve sufficiently high diffraction of light having entered the pixel 101, the depth of the trench may be larger than the width of the trench.

Since the scattering diffraction structure 328 is formed in the main surface 392 of the semiconductor layer 301 where light enters, the light having entered the pixel 101 is scattered. This causes the incident light to travel obliquely in the pixel 101, so that the optical path length larger than the thickness of the semiconductor layer 301 can be ensured, and the photoelectric conversion efficiency increases. Further, since the optical path length increases, it is possible to photoelectrically convert light of a longer wavelength than in a case where the scattering diffraction structure 328 is not provided.

In the scattering diffraction structure 328, when polygonal unit structures are periodically arranged as shown in FIG. 24B, the incident light is strongly diffracted in a particular direction. More specifically, in the orthogonal projection to the main surface 392 of the semiconductor layer 301, the light having entered a direction orthogonal to each side of the polygonal unit structure of the scattering diffraction structure 328 is diffracted. Hence, as shown in FIGS. 24A and 24B, the conductive portion 325 may not be arranged on a virtual line passing the center of the APD 201 and orthogonal to at least one side of the unit structure of the scattering diffraction structure 328. In a case of the scattering diffraction structure 328 shown in FIG. 24B, the incident light is diffracted in the vertex directions of the polygonal trench 324. If the conductive portion 325 is arranged in the direction to which the incident light is diffracted, the diffracted light may be absorbed by the conductive portion 325. To prevent this, the conductive portion 325 is not arranged in a region including a vertex of the polygonal trench 324 but arranged in a side portion of the polygonal trench 324. With this, it is possible to improve the sensitivity of the pixel 101 (APD 201) while suppressing a crosstalk.

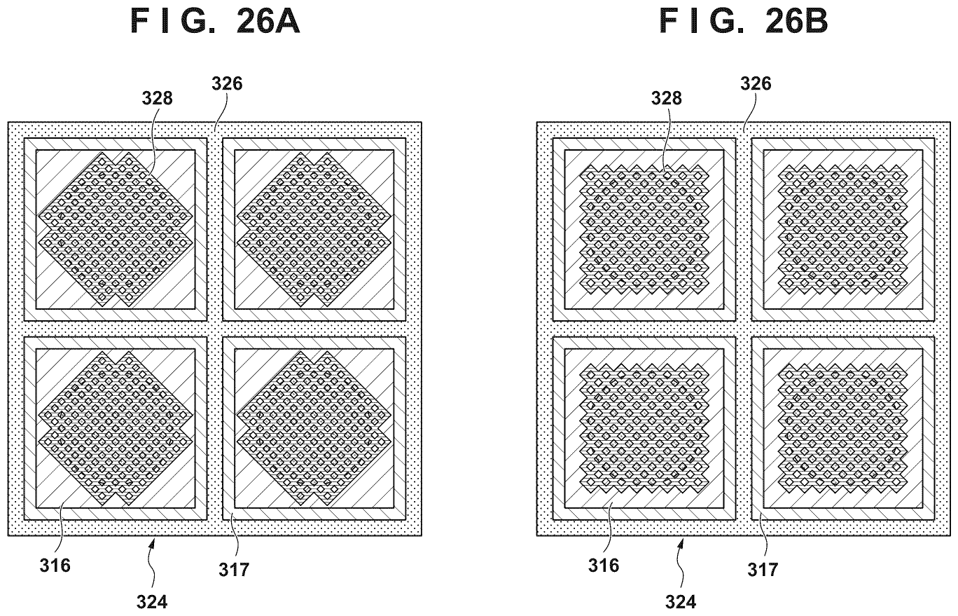

The shape of the scattering diffraction structure 328 in the orthogonal projection to the main surface 392 of the semiconductor layer 301 is not limited to an overall rectangular shape in which the rectangular unit structures rotated by 45° with respect to the rectangular trench 324 are periodically arranged as shown in FIG. 24B. As shown in FIG. 26A, the scattering diffraction structure 328 may have a shape in which some unit structures protrude from the overall rectangular shape shown in FIG. 24B. Alternatively, for example, as shown in FIGS. 26B, the overall shape may be a rectangular shape having the same rotation direction as the rectangular trench 324. In the shapes shown in FIGS. 26A and 26B, the area occupied by the scattering diffraction structure 328 is larger than in the shape shown in FIG. 24B. This causes more incident light to be diffracted, so that the sensitivity of the pixel 101 (APD 201) can be further improved.

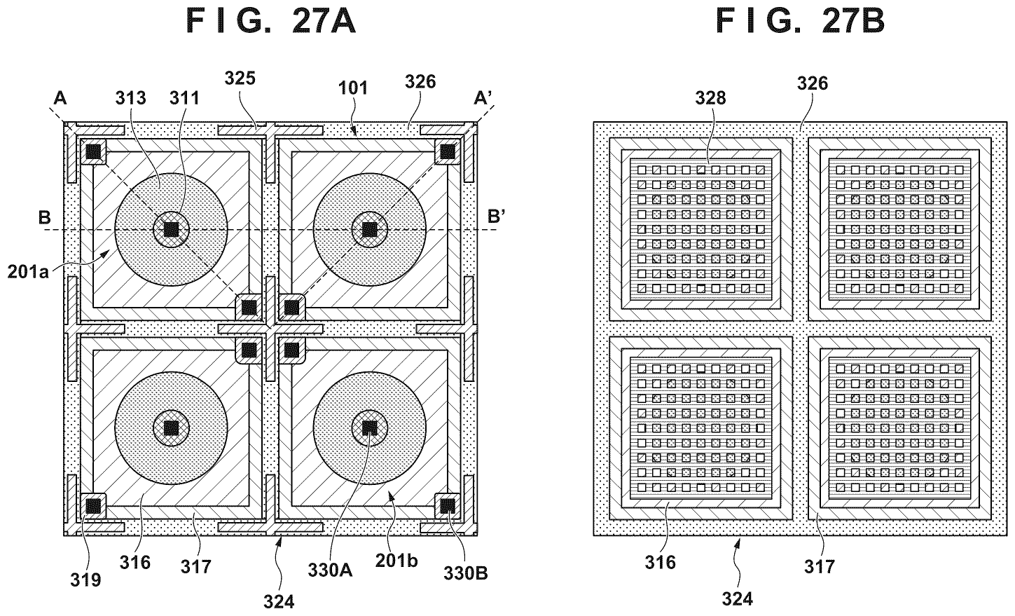

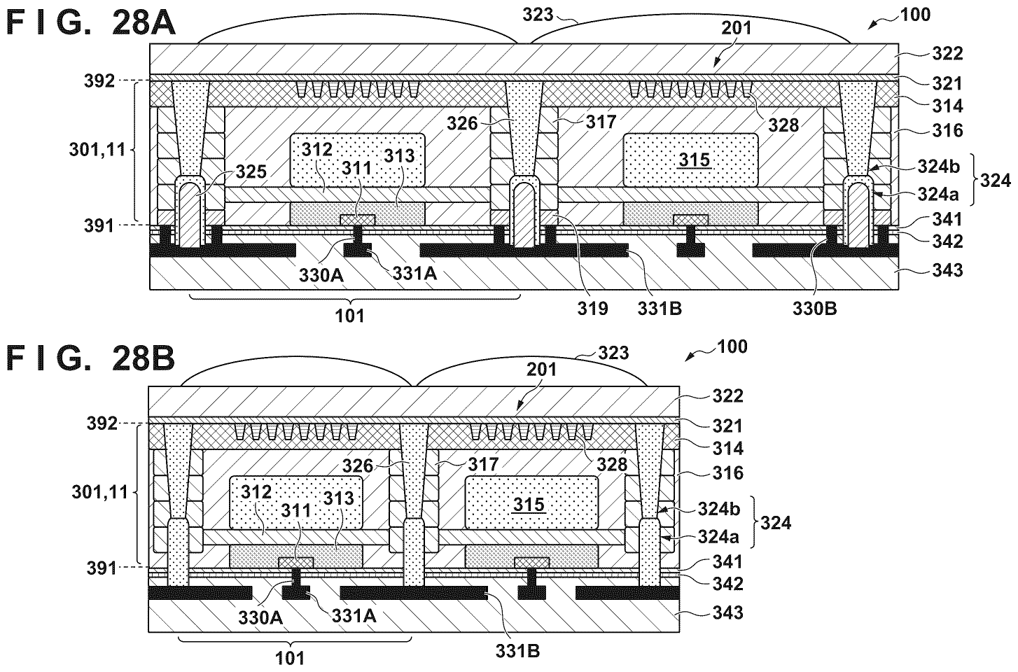

The unit structure of the scattering diffraction structure 328 is not limited to be rotated by 45° with respect to the rectangular trench 324. As shown in FIGS. 27A to 28B, rectangular unit structures having the same rotation direction as the rectangular trench 324 may be periodically arranged to form the scattering diffraction structure 328. Even in this case, as shown in FIGS. 27A and 27B, the conductive portion 325 may not be arranged on a virtual line passing the center of the APD 201 and orthogonal to at least one side of the unit structure of the scattering diffraction structure 328. For example, the conductive portion 325 can be arranged in a region including a vertex of the polygonal trench 324. That is, in the orthogonal projection to the main surface 392 (main surface 391) of the semiconductor layer 301, a portion of the trench 324 arranged to surround the APD 201a and a portion thereof arranged to surround the APD 201b may have polygonal shapes sharing one vertex, and the conductive portion 325 may be arranged at the shared vertex. Even in this case, in the orthogonal projection to the main surface 391 (main surface 392) of the semiconductor layer 301, the conductive portion 325 can include a portion arranged between the centers of the APDs 201a and 201b adjacent to each other. Also in the arrangement shown in FIGS. 27A to 28B, since the scattering diffraction structure 328 is arranged, the sensitivity of the pixel 101 (APD 201) can be improved.

As shown in FIG. 24A, in the orthogonal projection to the main surface 391 of the semiconductor layer 301, the end portion of the conductive portion 325 may be curved. When the end portion of the conductive portion 325 has a rounded shape, in other words, when the end portion of the trench for embedding the conductive portion 325 has a rounded shape, for example, the coverage of the trench with a barrier metal arranged in the conductive portion 325 improves. This leads to an improvement of the stability (for example, the defect rate of the pixel 101) during manufacturing the photoelectric conversion apparatus 100. The shape of the end portion of the conductive portion 325 shown in FIG. 24A can be applied to each arrangement described above. Further, the other arrangements described above may be combined, as appropriate. For example, the scattering diffraction structure 328 may be added to the arrangement shown in FIGS. 22A to 23B.

An application example of the photoelectric conversion apparatus 100 in which the above-described pixels 101 are arranged will be described below.

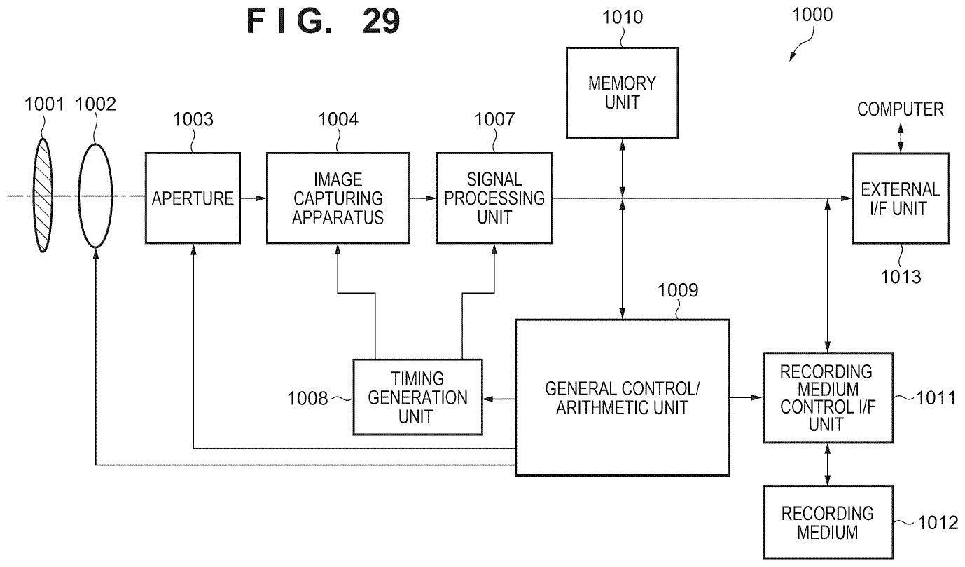

FIG. 29 is a block diagram showing the schematic arrangement of a photoelectric conversion system. The photoelectric conversion apparatus 100 described in each embodiment described above is applicable to various kinds of photoelectric conversion systems. Examples of photoelectric conversion systems to which the photoelectric conversion apparatus is applicable are a digital still camera, a digital camcorder, a monitoring camera, a copying machine, a facsimile apparatus, a mobile phone, an in-vehicle camera, and an observation satellite. A camera module including an optical system such as a lens and an image capturing apparatus is also included in the photoelectric conversion systems. FIG. 29 exemplarily shows the block diagram of a digital still camera as an example of these.

A photoelectric conversion system 1000 exemplarily shown in FIG. 29 includes an image capturing apparatus 1004 as an example of the photoelectric conversion apparatus, a lens 1002 that forms an optical image of an object on the image capturing apparatus 1004, an aperture 1003 configured to change the amount of light passing through the lens 1002, and a barrier 1001 configured to protect the lens 1002. The lens 1002 and the aperture 1003 form an optical system (optical apparatus) that condenses light to the image capturing apparatus 1004. The image capturing apparatus 1004 is the photoelectric conversion apparatus 100 (image capturing apparatus) according to one of the above-described embodiments, and converts the optical image formed by the lens 1002 into an electrical signal.

The photoelectric conversion system 1000 also includes a signal processing unit 1007 that is an image generation unit configured to generate an image by processing an output signal output from the image capturing apparatus 1004. The signal processing unit 1007 functions as a processing apparatus that performs an operation of performing various kinds of correction and compression as needed, thereby outputting image data. The signal processing unit 1007 may be formed on a semiconductor substrate on which the image capturing apparatus 1004 is provided or may be formed on a semiconductor substrate different from the image capturing apparatus 1004. In addition, the image capturing apparatus 1004 and the signal processing unit 1007 may be formed on the same semiconductor substrate.

The photoelectric conversion system 1000 further includes a memory unit 1010 configured to temporarily store image data, and an external interface unit (external I/F unit) 1013 configured to communicate with an external computer or the like. Furthermore, the photoelectric conversion system 1000 includes a recording medium 1012 such as a semiconductor memory configured to record or read out image capturing data, and a recording medium control interface unit (recording medium control I/F unit) 1011 configured to perform record or readout for the recording medium 1012. The recording medium control I/F unit 1011 and the recording medium 1012 can form a part of a recording apparatus. Note that the recording medium 1012 may be incorporated in the photoelectric conversion system 1000 or may be detachable.

Furthermore, the photoelectric conversion system 1000 includes a general control/arithmetic unit 1009 that controls various kinds of operations and the entire digital still camera, and a timing generation unit 1008 that outputs various kinds of timing signals to the image capturing apparatus 1004 and the signal processing unit 1007. The general control/arithmetic unit 1009 and the timing generation unit 1008 can form a part of a control apparatus configured to control an operation of the photoelectric conversion system 1000. In this example, the timing signal and the like may be input from the outside, and the photoelectric conversion system 1000 need only include at least the image capturing apparatus 1004, and the signal processing unit 1007 that processes an output signal output from the image capturing apparatus 1004.

The image capturing apparatus 1004 outputs an image capturing signal to the signal processing unit 1007. The signal processing unit 1007 executes predetermined signal processing for the image capturing signal output from the image capturing apparatus 1004, and outputs image data. The signal processing unit 1007 generates an image using the image capturing signal. Although not shown in FIG. 29, a display apparatus such as a display for displaying the generated image may be arranged in the photoelectric conversion system 1000. As described above, according to this embodiment, it is possible to implement the photoelectric conversion system 1000 to which the photoelectric conversion apparatus 100 (image capturing apparatus) according to one of the above-described embodiments is applied.

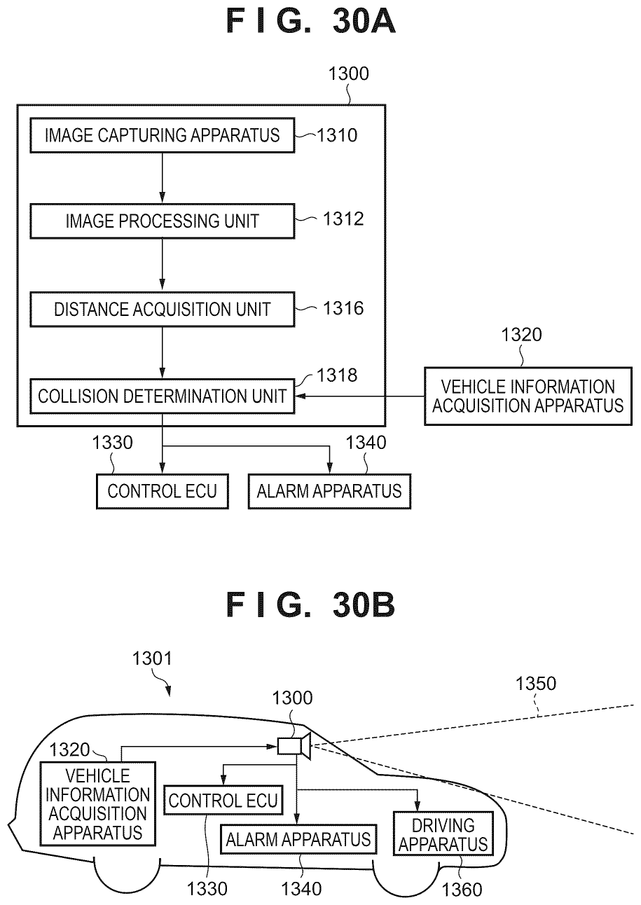

FIGS. 30A and 30B are views showing the arrangements of a photoelectric conversion system 1300 and a moving body 1301, respectively. FIG. 30A shows an example of a photoelectric conversion system concerning an in-vehicle camera. The photoelectric conversion system 1300 includes an image capturing apparatus 1310. The image capturing apparatus 1310 is the photoelectric conversion apparatus 100 (image capturing apparatus) described in one of the above-described embodiments. The photoelectric conversion system 1300 includes an image processing unit 1312 that performs image processing for a plurality of image data acquired by the image capturing apparatus 1310. The photoelectric conversion system 1300 also includes a distance acquisition unit 1316 that calculates the distance up to a target object, and a collision determination unit 1318 that determines, based on the calculated distance, whether there is collision possibility. Here, the distance acquisition unit 1316 may acquire distance information up to a target object by using Time of Flight (ToF) method, or may acquire distance information by using parallax information or the like. That is, the distance information is information concerning a parallax, a defocus amount, a distance up to a target object, and the like. The collision determination unit 1318 may determine collision possibility using one of the pieces of distance information. The distance acquisition unit 1316 may be implemented by exclusively designed hardware, or may be implemented by a software module. The distance acquisition unit 1316 may be implemented by a Field Programmable Gate Array (FPGA), Application Specific Integrated Circuit (ASIC), or the like, or may be implemented by a combination of these.

The photoelectric conversion system 1300 is connected to a vehicle information acquisition apparatus 1320, and can acquire vehicle information such as a vehicle speed, a yaw rate, and a steering angle. The photoelectric conversion system 1300 is also connected to an ECU 1330 that is a control apparatus (control unit) configured to output a control signal for generating a braking force to the vehicle based on the determination result of the collision determination unit 1318. Furthermore, the photoelectric conversion system 1300 is connected to an alarm apparatus 1340 that generates an alarm to the driver based on the determination result of the collision determination unit 1318. For example, if collision possibility is high as the determination result of the collision determination unit 1318, the ECU 1330 controls a driving apparatus (machine apparatus) 1360 to perform braking, releasing the accelerator pedal, or suppressing the engine output, thereby controlling the vehicle for avoiding collision and reducing damage. The alarm apparatus 1340 sounds an alarm, displays alarm information on the screen of a car navigation system or the like, or applies a vibration to the seat belt or a steering wheel, thereby making an alarm to the user.

In this embodiment, the periphery of the vehicle (moving body 1301), for example, the front or rear side is captured by the photoelectric conversion system 1300. FIG. 30B shows the photoelectric conversion system when capturing the front side (image capturing range 1350) of the vehicle. The vehicle information acquisition apparatus 1320 sends an instruction to the photoelectric conversion system 1300 or the image capturing apparatus 1310. With this configuration, it is possible to further improve the accuracy of distance measurement.

An example in which control is executed so as not to collide with another vehicle has been explained above. The photoelectric conversion system 1300 can also be applied to control of performing automated driving following another vehicle or control of performing automated driving without deviating from a lane. Furthermore, the photoelectric conversion system 1300 can be applied not only to a vehicle such as an automobile but also to, for example, a moving body (moving apparatus) such as a ship, an airplane, or an industrial robot. The moving body includes one or both of a driving force generation unit that generates a driving force mainly used for moving the moving body and a rotating body mainly used for moving the moving body. The driving force generation unit can be an engine, a motor, or the like. The rotating body can be a tire, a wheel, a ship screw, an aircraft propeller, or the like. In addition, the photoelectric conversion system can be applied not only to a moving body but also to equipment that broadly uses object recognition, such as an intelligent transport system (ITS).

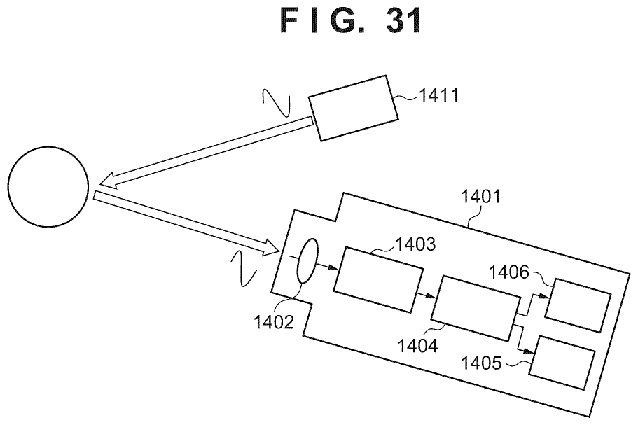

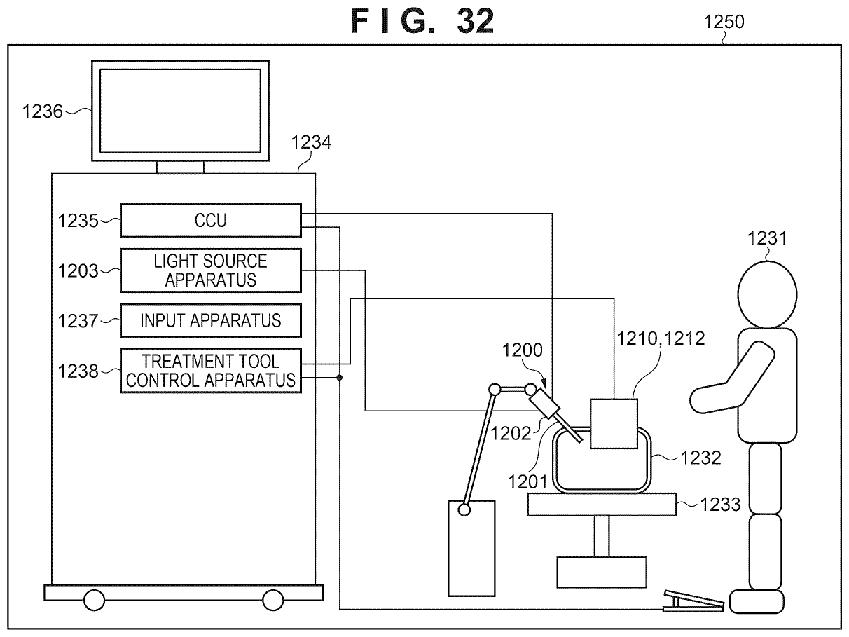

FIG. 31 is a block diagram showing an example of the arrangement of a distance image sensor 1401 as the photoelectric conversion system. As shown in FIG. 31, the distance image sensor 1401 includes an optical system 1402, a photoelectric conversion apparatus 1403, an image processing circuit 1404, a monitor 1405, and a memory 1406. Then, the distance image sensor 1401 can receive light (modulated light or pulsed light) projected from a light source apparatus 1411 toward an object and reflected by the surface of the object, thereby acquiring a distance image corresponding to the distance up to the object.

The optical system 1402 is formed by including one or a plurality of lenses, and guides image light (incident light) from the object to the photoelectric conversion apparatus 1403 and forms an image on the light-receiving surface (sensor portion) of the photoelectric conversion apparatus 1403.

As the photoelectric conversion apparatus 1403, the photoelectric conversion apparatus 100 of each of the above-described embodiments is applied, and a distance signal indicating a distance obtained from a light reception signal output from the photoelectric conversion apparatus 1403 is supplied to the image processing circuit 1404.

The image processing circuit 1404 performs image processing of creating a distance image based on the distance signal supplied from the photoelectric conversion apparatus 1403. Then, the distance image (image data) obtained by the image processing is supplied to and displayed on the monitor 1405, and supplied to and stored (recorded) in the memory 1406.

The distance image sensor 1401 having such arrangement can acquire, for example, a more correct distance image along with improvement in characteristic of pixels by applying the above-described photoelectric conversion apparatus 100.

FIG. 32 is a view showing an example of the schematic arrangement of an endoscopic surgery system 1250 as the photoelectric conversion system. FIG. 32 shows a state in which an operator (doctor) 1231 operates on a patient 1232 on a patient bed 1233 using the endoscopic surgery system 1250. As shown in FIG. 32, the endoscopic surgery system 1250 is formed from an endoscope 1200, a surgical tool 1210, and a cart 1234 on which various apparatuses for endoscopic surgery are mounted.

The endoscope 1200 includes a lens barrel 1201 including a region of a predetermined length from the distal end, which is inserted into the body cavity of the patient 1232, and a camera head 1202 connected to the proximal end of the lens barrel 1201. In the example shown in FIG. 32, the endoscope 1200 formed as a so-called hard mirror including the hard lens barrel 1201 is shown but the endoscope 1200 may be formed as a so-called soft mirror including a soft lens barrel.

An opening in which an objective lens is fitted is provided at the distal end of the lens barrel 1201. A light source apparatus 1203 is connected to the endoscope 1200, and light generated by the light source apparatus 1203 is guided to the distal end of the lens barrel by a light guide extended inside the lens barrel 1201, and is emitted to an observation target in the body cavity of the patient 1232 via the objective lens. Note that the endoscope 1200 may be a forward-viewing endoscope or may be a forward-oblique viewing endoscope or side-viewing endoscope.

An optical system and a photoelectric conversion apparatus are provided in the camera head 1202, and reflected light (observation light) from the observation target is condensed by the optical system to the photoelectric conversion apparatus. The observation light is photoelectrically converted by the photoelectric conversion apparatus to generate an electrical signal corresponding to the observation light, that is, an image signal corresponding to an observation image. As the photoelectric conversion apparatus, the photoelectric conversion apparatus 100 (image capturing apparatus) described in each of the above-described embodiments can be used. The image signal is transmitted as RAW data to a Camera Control Unit (CCU) 1235.

The CCU 1235 is formed by a Central Processing Unit (CPU), a Graphics Processing Unit (GPU), and the like, and comprehensively controls the operations of the endoscope 1200 and a display apparatus 1236. Furthermore, the CCU 1235 receives an image signal from the camera head 1202, and performs, for the image signal, various kinds of image processes such as development processing (demosaic processing) for displaying an image based on the image signal.

Under the control of the CCU 1235, the display apparatus 1236 displays the image based on the image signal having undergone the image processing by the CCU 1235.

The light source apparatus 1203 is formed from a light source such as a Light Emitting Diode (LED), and supplies, to the endoscope 1200, irradiation light at the time of imaging an operation portion or the like.

An input apparatus 1237 is an input interface to the endoscopic surgery system 1250. The user can input various kinds of information or instructions to the endoscopic surgery system 1250 via the input apparatus 1237.

A treatment tool control apparatus 1238 controls driving of an energy treatment tool 1212 for ablation or incision of the tissue, sealing of a blood vessel, or the like.

The light source apparatus 1203 that supplies, to the endoscope 1200, irradiation light at the time of imaging an operation portion can be formed from, for example, a white light source formed by an LED, a laser light source, or a combination thereof. If the white light source is formed by a combination of RGB laser light sources, it is possible to accurately control the output intensity and output timing of each color (each wavelength), and thus the light source apparatus 1203 can adjust the white balance of a captured image. In this case, the observation target is time-divisionally irradiated with laser beams from the RGB laser light sources, respectively, and driving of the image sensor of the camera head 1202 is controlled in synchronism with the irradiation timings, thereby making it possible to time-divisionally capture images respectively corresponding to R, G, and B. In this method, it is possible to obtain a color image without providing color filters in the image sensor.

Driving of the light source apparatus 1203 may be controlled to change the intensity of light to be output for every predetermined time. It is possible to time-divisionally acquire images by controlling driving of the image sensor of the camera head 1202 in synchronism with the timing of changing the intensity of the light, and combine the images, thereby generating an image of a high dynamic range without so-called shadow detail loss or highlight detail loss.

The light source apparatus 1203 may be configured to supply light in a predetermined wavelength band corresponding to special light observation. In special light observation, for example, the wavelength dependency of light absorption in the body tissue is used. More specifically, by performing irradiation with light in a narrow band, as compared with irradiation light (that is, white light) at the time of normal observation, predetermined tissue such as a blood vessel in the mucous membrane surface layer is captured with high contrast. Alternatively, in special light observation, fluorescence observation for obtaining an image by using fluorescence generated by performing irradiation with excitation light may be performed. In fluorescence observation, it is possible to, for example, irradiate body tissue with excitation light and observe fluorescence from the body tissue, or locally inject a reagent such as indocyanine green (ICG) to body tissue while irradiating the body tissue with excitation light corresponding to the fluorescence wavelength of the reagent, thereby obtaining a fluorescence image. The light source apparatus 1203 can be configured to supply narrow band light and/or excitation light corresponding to such special light observation.

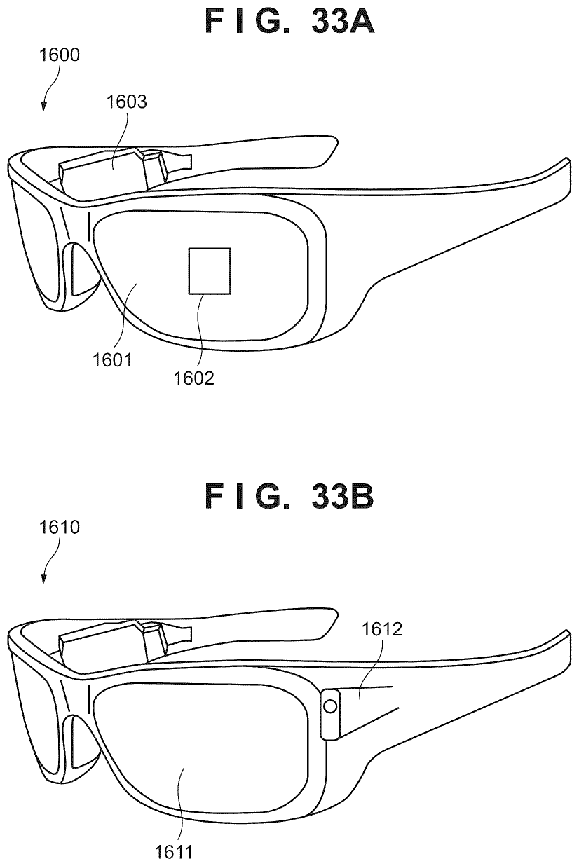

FIGS. 33A and 33B describe glasses 1600, 1610 (smartglasses) as the photoelectric conversion system. The glasses 1600 shown in FIG. 33A include a photoelectric conversion apparatus 1602. The photoelectric conversion apparatus 1602 is the photoelectric conversion apparatus 100 (image capturing apparatus) described in each embodiment described above. A display apparatus including the light emitting apparatus such as an OLED or LED may be provided on the back surface side of a lens 1601. One or a plurality of photoelectric conversion apparatuses 1602 may be provided. Alternatively, a plurality of kinds of photoelectric conversion apparatuses may be used in combination. The arrangement position of the photoelectric conversion apparatus 1602 is not limited to that shown in FIG. 33A.

The glasses 1600 further include a control apparatus 1603. The control apparatus 1603 functions as a power supply that supplies electric power to the photoelectric conversion apparatus 1602 and the above-described display apparatus. In addition, the control apparatus 1603 controls the operations of the photoelectric conversion apparatus 1602 and the display apparatus. An optical system configured to condense light to the photoelectric conversion apparatus 1602 is formed on the lens 1601.

FIG. 33B describes glasses 1610 (smartglasses) according to one application example. The glasses 1610 include a control apparatus 1612, and a photoelectric conversion apparatus corresponding to the photoelectric conversion apparatus 1602 and a display apparatus are mounted on the control apparatus 1612. The photoelectric conversion apparatus in the control apparatus 1612 and an optical system configured to project light emitted from the display apparatus are formed in a lens 1611, and an image is projected to the lens 1611. The control apparatus 1612 functions as a power supply that supplies electric power to the photoelectric conversion apparatus and the display apparatus, and controls the operations of the photoelectric conversion apparatus and the display apparatus. The control apparatus may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a plan view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display apparatus according to the embodiment can include a photoelectric conversion apparatus including a light receiving element, and control a displayed image of the display apparatus based on the line-of-sight information of the user from the photoelectric conversion apparatus.

More specifically, the display apparatus decides a first visual field region at which the user is gazing and a second visual field region other than the first visual field region based on the line-of-sight information. The first visual field region and the second visual field region may be decided by the control apparatus of the display apparatus, or those decided by an external control apparatus may be received. In the display region of the display apparatus, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority may be decided from the first display region and the second display region based on line-of-sight information. The first visual field region and the second visual field region may be decided by the control apparatus of the display apparatus, or those decided by an external control apparatus may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target object ahead the line of sight from the image of the eyeball using the image of the eyeball and the direction of actual viewing of the eyeball in the image as supervised data. The AI program may be held by the display apparatus, the photoelectric conversion apparatus, or an external apparatus. If the external apparatus holds the AI program, it is transmitted to the display apparatus via communication.

If display control is performed based on visual detection, this can be applied to smartglasses further including a photoelectric conversion apparatus configured to capture the image of the outside. The smartglasses can display the captured outside image information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-005561, filed Jan. 17, 2024, which is hereby incorporated by reference herein in its entirety.

What is claimed is:

1. A photoelectric conversion apparatus comprising: a semiconductor layer having a first main surface and a second main surface and including a first avalanche photodiode and a second avalanche photodiode adjacent to each other; and a trench extending from the first main surface toward the second main surface, wherein
at least a part of the trench is arranged between the first avalanche photodiode and the second avalanche photodiode,
a first conductive portion and a second conductive portion are arranged in the trench, and
in an orthogonal projection to the first main surface, the first conductive portion and the second conductive portion are arranged apart from each other in the trench.

2. The apparatus according to claim 1, wherein each of the first avalanche photodiode and the second avalanche photodiode includes a first semiconductor region of a first conductivity type arranged between the first main surface and the second main surface, and a second semiconductor region of a second conductivity type arranged between the first semiconductor region and the second main surface and configured to induce avalanche breakdown between the first semiconductor region and the second semiconductor region.

3. The apparatus according to claim 2, wherein in a depth direction as a direction connecting the first main surface and the second main surface, the first conductive portion and the second conductive portion are arranged to at least a depth where the second semiconductor region is arranged.

4. The apparatus according to claim 1, wherein an insulator is arranged between the first conductive portion and the second conductive portion in the trench.

5. The apparatus according to claim 4, wherein the insulator includes a first insulating layer and a second insulating layer arranged between the first insulating layer and an inner wall of the trench and containing a material different from the first insulating layer.

6. The apparatus according to claim 5, wherein the second insulating layer is arranged between the inner wall of the trench and the first conductive portion and between the inner wall of the trench and the second conductive portion.

7. The apparatus according to claim 1, wherein the trench includes a portion arranged to surround the first avalanche photodiode, and a portion arranged to surround the second avalanche photodiode.

8. The apparatus according to claim 7, wherein in an orthogonal projection to the first main surface, the portion arranged to surround the first avalanche photodiode and the portion arranged to surround the second avalanche photodiode are continuous.

9. The apparatus according to claim 1, wherein in an orthogonal projection to the first main surface, the first conductive portion includes a portion arranged between a center of the first avalanche photodiode and a center of the second avalanche photodiode.

10. The apparatus according to claim 9, wherein
in an orthogonal projection to the first main surface,
the trench includes a first polygonal-shaped portion arranged to surround the first avalanche photodiode and a second polygonal-shaped portion arranged to surround the second avalanche photodiode, and
the first polygonal-shaped portion and the second polygonal-shaped portion share one side,
the first conductive portion is arranged in the one side, and
the second conductive portion is not arranged in the one side.

11. The apparatus according to claim 9, wherein
in an orthogonal projection to the first main surface,
the trench includes a first polygonal-shaped portion arranged to surround the first avalanche photodiode and a second polygonal-shaped portion arranged to surround the second avalanche photodiode, and
the first polygonal-shaped portion and the second polygonal-shaped portion share one vertex, and
the first conductive portion includes a portion arranged at the one vertex.

12. The apparatus according to claim 9, wherein
the semiconductor layer further includes a third avalanche photodiode arranged adjacent to the first avalanche photodiode via the trench, and
the second conductive portion includes a portion arranged between a center of the first avalanche photodiode and a center of the third avalanche photodiode.

13. The apparatus according to claim 1, wherein a common potential is supplied to the first conductive portion and the second conductive portion.

14. The apparatus according to claim 1, wherein in an orthogonal projection to the first main surface, an end portion of each of the first conductive portion and the second conductive portion is curved.

15. The apparatus according to claim 1, wherein the apparatus is configured such that light enters from the second main surface.

16. The apparatus according to claim 15, wherein
the trench includes a first portion arranged from the first main surface toward the second main surface, and a second portion arranged between the first portion and the second main surface, and
a step is generated in a connection portion between the first portion and the second portion.

17. The apparatus according to claim 16, wherein
the second portion has a tapered shape with a width decreasing from the second main surface toward the first main surface, and
in the connection portion, a width of the first portion is larger than a width of the second portion.

18. The apparatus according to claim 16, wherein the first conductive portion and the second conductive portion are arranged in the first portion.

19. The apparatus according to claim 16, wherein the first conductive portion and the second conductive portion are not arranged in the second portion.

20. The apparatus according to claim 16, wherein a reflecting member is arranged in the second portion.

21. The apparatus according to claim 16, wherein the first conductive portion and the second conductive portion are arranged in the second portion.

22. The apparatus according to claim 21, wherein a third conductive portion is arranged over the entire first portion.

23. The apparatus according to claim 16, wherein the trench extends through the semiconductor layer.

24. The apparatus according to claim 16, wherein a scattering diffraction structure is provided in the second main surface so as to at least partially overlap the first avalanche photodiode.

25. The apparatus according to claim 24, wherein in an orthogonal projection to the second main surface,
polygonal-shaped unit structures are periodically arranged in the scattering diffraction structure, and
the first conductive portion and the second conductive portion are not arranged on a virtual line passing a center of the first avalanche photodiode and orthogonal to at least one side of the unit structure.

26. The apparatus according to claim 1, wherein
the semiconductor layer includes a third avalanche photodiode and a fourth avalanche photodiode,
in a first direction, the first avalanche photodiode and the second avalanche photodiode are adjacent to each other,
in the first direction, the third avalanche photodiode and the fourth avalanche photodiode are adjacent to each other,
in a second direction intersecting the first direction, the first avalanche photodiode and the third avalanche photodiode are adjacent to each other,
at least a part of the trench is arranged between the first avalanche photodiode and the second avalanche photodiode, between the third avalanche photodiode and the fourth avalanche photodiode, and between the first avalanche photodiode and the fourth avalanche photodiode,
the first conductive portion is arranged between the first avalanche photodiode and the second avalanche photodiode,
the second conductive portion is arranged between the third avalanche photodiode and the fourth avalanche photodiode, and
an insulator is arranged between the first avalanche photodiode and the fourth avalanche photodiode.

27. A photoelectric conversion system comprising:
the photoelectric conversion apparatus according to claim 1; and
a signal processor configured to generate an image using a signal output from the photoelectric conversion apparatus.

28. A moving body that includes the photoelectric conversion apparatus according to claim 1, comprising
a controller configured to control movement of the moving body using a signal output by the photoelectric conversion apparatus.

29. Equipment that comprises the photoelectric conversion apparatus according to claim 1, further comprising at least any of:
an optical apparatus corresponding to the photoelectric conversion apparatus,
a control apparatus configured to control the photoelectric conversion apparatus;
a processing apparatus configured to process a signal output from the photoelectric conversion apparatus;
a display apparatus configured to display information obtained by the photoelectric conversion apparatus;
a storage apparatus configured to store information obtained by the photoelectric conversion apparatus; and
a mechanical apparatus configured to operate based on information obtained by the photoelectric conversion apparatus.
